(19) United States
(12) Patent Application Publication
(10) Pub. No.: US 2025/0140749 A1
(43) Pub. Date: May 1, 2025

(54) SEMICONDUCTOR PACKAGE STRUCTURE AND METHOD OF MANUFACTURING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/520,946

(22) Filed: Nov. 28, 2023

Related U.S. Application Data
(62) Division of application No. 18/385,499, filed on Oct. 31, 2023.

(51) Int. Cl. H01L 25/065; H01L 21/48; H01L 23/00; H01L 23/498; H01L 23/538; H01L 25/00; H01L 25/18; H10B 80/00

(52) U.S. Cl. CPC H01L 25/0657; H01L 21/4857; H01L 21/486; H01L 23/49833; H01L 23/5383; H01L 24/08; H01L 24/80; H01L 25/18; H01L 25/50; H10B 80/00; H01L 24/45; H01L 24/48; H01L 2224/08225; H01L 2224/45124; H01L 2224/45139; H01L 2224/45144; H01L 2224/45147; H01L 2224/45184; H01L 2224/48091; H01L 2224/48227; H01L 2224/80424; H01L 2224/80439; H01L 2224/80444; H01L 2224/80447; H01L 2224/80466; H01L 2224/80481; H01L 2224/80484; H01L 2224/80486; H01L 2225/0651; H01L 2225/06548; H01L 2225/06572; H01L 2924/04941; H01L 2924/04953

(57) ABSTRACT

A semiconductor structure and a manufacturing method are provided. The semiconductor structure includes a first substrate having a first side and a second side opposite to the first side, wherein the first side includes a recess recessed from the first side; a first semiconductor die arranged in the recess and bonded to the first side of the first substrate; a second semiconductor die bonded to the second side of the first substrate; a second substrate electrically bonded to the first side of the first substrate; a plurality of conductive vias positioned along the second substrate and extending through the second substrate; and a plurality of conductive lines positioned on the second substrate.

### CROSS-REFERENCE TO RELATED APPLICATION

This application is a divisional application of U.S. Non-Provisional application Ser. No. 18/385,499 filed Oct. 31, 2023, which is incorporated herein by reference in its entirety.

### TECHNICAL FIELD

The present disclosure relates to a semiconductor structure and a method of manufacturing the semiconductor structure. Particularly, the bonding structure includes a semiconductor package structure and the method of forming the semiconductor interconnect package structure.

### DISCUSSION OF THE BACKGROUND

As the semiconductor industry has advanced into higher technology nodes in pursuit of greater device density and performance, it has achieved an advanced level of precision in photolithography. Further reductions in device sizes require a proportional decrease in element dimensions and distances between them. However, the reduced dimensions of the elements and the distances between them have posed challenges for precise control of these parameters.

The bonding structure of the devices is critical for maintaining electrical connect ability with external devices. To facilitate this, an interface is created between the semiconductor device and other devices in the package, which consists of bonding bumps or connectors forming a bonding structure with sufficient connections. Due to the limitations of bonding pad or connector areas, resulting from the reduced device footprint and increased number of input/output terminals, it is imperative to create a sufficient bonding structure. As such, it is necessary to establish an enhanced bonding structure for a dependable connection interface within the bonded package for semiconductor devices.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure, which includes: a first substrate having a first side and a second side opposite to the first side, wherein the first side includes a recess recessed from the first side; a first semiconductor die arranged in the recess and bonded to the first side of the first substrate; a second semiconductor die bonded to the second side of the first substrate; a second substrate electrically bonded to the first side of the first substrate; a plurality of conductive vias positioned along the second substrate and extending through the second substrate; and a plurality of conductive lines positioned on the second substrate.

According to some embodiments of the present disclosure, the conductive via comprises a filler layer positioned along the second substrate and extending through the second substrate; and two isolation layers positioned on two sides of the filler layer, wherein the two isolation layers are formed of silicon oxide, silicon nitride, silicon oxynitride, tetra-ethyl ortho-silicate, or parylene, epoxy, poly(p-xylene).

According to some embodiments of the present disclosure, the conductive via comprises a seed layer positioned between the two isolation layers and the filler layer and between the filler layer and the corresponding conductive line positioned on the second substrate.

According to some embodiments of the present disclosure, the conductive via comprises an adhesive layer positioned between the seed layer and the two isolation layers and between the seed layer and the corresponding conductive line on the second substrate, wherein the adhesive layer is formed of titanium, tantalum, titanium tungsten, or manganese nitride.

According to some embodiments of the present disclosure, the conductive via comprises a barrier layer positioned between the adhesive layer and the two isolation layers and between the adhesive layer and the corresponding conductive line on the second substrate, wherein the barrier layer is formed of tantalum, tantalum nitride, titanium, titanium nitride, rhenium, nickel boride, or tantalum nitride/tantalum bilayer.

According to some embodiments of the present disclosure, the two isolation layers have a thickness between about 50 nm and about 200 nm.

According to some embodiments of the present disclosure, the two isolation layers have a thickness between about 1 μm and about 5 μm.

According to some embodiments of the present disclosure, the seed layer is formed of copper or ruthenium.

According to some embodiments of the present disclosure, the filler layer is copper.

According to some embodiments of the present disclosure, the semiconductor structure further comprises a molding material encapsulating the first substrate, the second substrate, the first semiconductor die, and the second semiconductor die.

According to some embodiments of the present disclosure, the molding material includes epoxy resin, PI, BCB, PBO, or PEEK.

According to some embodiments of the present disclosure, the semiconductor structure further comprises a plurality of connectors, wherein each of the connectors positioned on the corresponding conductive line.

According to some embodiments of the present disclosure, the plurality of connectors is formed of Sn, Pb, Ni, Au, Ag, Cu, Bi, or combinations thereof.

Another aspect of the present disclosure provides a semiconductor structure, which includes: a first substrate including a horizontal portion and a protrusion portion extending on a peripheral region of the horizontal portion; a first semiconductor die bonded to a first side of the horizontal portion; a second semiconductor die bonded to a second side of the horizontal portion and laterally surrounded by the protrusion portion; a second substrate electrically bonded to the protrusion portion of the first substrate; a passivation layer positioned on the second substrate; and a barrier layer positioned on the second substrate and in the passivation layer.

According to some embodiments of the present disclosure, the passivation layer defines a plurality of openings disposed along the passivation layer to expose a portion of the second substrate.

According to some embodiments of the present disclosure, the barrier layer is positioned in the openings.

According to some embodiments of the present disclosure, a thickness of the passivation layer is greater than a thickness of the barrier layer.

According to some embodiments of the present disclosure, the semiconductor structure further comprising a plurality of connectors positioned on the barrier layer.

According to some embodiments of the present disclosure, a first portion of the connector is extending to the passivation layer, completely filled the opening, and disposed on the barrier layer.

According to some embodiments of the present disclosure, a second portion of the connector is protruding from a plane coplanar with the top surface of the passivation layer and disposed on the first portion of the connector.

According to some embodiments of the present disclosure, the passivation layer is formed of polybenzoxazole, polyimide, benzocyclobutene, solder resist film, the like, or a combination thereof.

According to some embodiments of the present disclosure, the passivation layer is formed of silicon nitride, silicon oxide, silicon oxynitride, silicon nitride oxide, phosphosilicate glass, borosilicate glass, boron-doped phosphosilicate glass, or a combination thereof.

According to some embodiments of the present disclosure, the barrier layer is formed of aluminum fluoride, zinc oxide.

According to some embodiments of the present disclosure, the sidewall of the opening is substantially vertical or tapered.

According to some embodiments of the present disclosure, the connector is a solder joint.

According to some embodiments of the present disclosure, the solder joint is formed of tin, silver, or copper.

According to some embodiments of the present disclosure, the semiconductor structure further comprises a molding material encapsulating the first substrate, the second substrate, the first semiconductor die, and the second semiconductor die.

According to some embodiments of the present disclosure, the molding material includes epoxy resin, PI, BCB, PBO, or PEEK.

Yet another aspect of the present disclosure provides a semiconductor structure, which includes: a first substrate having a first side and a second side opposite to the first side, wherein the first side includes a recess recessed from the first side; a first semiconductor die arranged in the recess and bonded to the first side of the first substrate; a second semiconductor die bonded to the second side of the first substrate; a second substrate electrically bonded to the first side of the first substrate; a plurality of conductive vias positioned along the second substrate and extending through the second substrate; a passivation layer positioned on the second substrate; and a barrier layer positioned on the second substrate and in the passivation layer.

According to some embodiments of the present disclosure, the conductive via comprises: two isolation layers conformally formed on two sidewalls of the via opening; a via barrier layer conformally formed on the isolation layer and on the bottom surface of the via opening, wherein the via barrier layer has a U-shaped cross-sectional profile and is formed of tantalum, tantalum nitride, titanium, titanium nitride, rhenium, nickel boride, or tantalum nitride/tantalum bilayer; an adhesive layer conformally formed on the barrier layer, wherein the adhesive layer has a U-shaped cross-sectional profile and is formed of titanium, tantalum, titanium tungsten, or manganese nitride; a seed layer conformally formed on the adhesive layer, wherein the seed layer has a U-shaped cross-sectional profile and is formed of copper or ruthenium; and a filler layer formed on the seed layer and completely fill the via opening, wherein the filler layer is copper.

According to some embodiments of the present disclosure, the two isolation layers are formed of silicon oxide, silicon nitride, silicon oxynitride, or tetra-ethyl ortho-silicate.

According to some embodiments of the present disclosure, the two isolation layers have a thickness between about 50 nm and about 200 nm.

According to some embodiments of the present disclosure, the two isolation layers are formed of parylene, epoxy, or poly(p-xylene).

According to some embodiments of the present disclosure, the two isolation layers have a thickness between about 1 μm and about 5 μm.

According to some embodiments of the present disclosure, the adhesive layer has a thickness between about 5 nm and about 50 nm.

According to some embodiments of the present disclosure, the seed layer has a thickness between about 10 nm and about 40 nm.

According to some embodiments of the present disclosure, the passivation layer defines a plurality of openings disposed along the passivation layer to expose a portion of the second substrate.

According to some embodiments of the present disclosure, the barrier layer is positioned in the openings.

According to some embodiments of the present disclosure, a thickness of the passivation layer is greater than a thickness of the barrier layer.

According to some embodiments of the present disclosure, the semiconductor structure further comprising a connector positioned on the barrier layer.

According to some embodiments of the present disclosure, a first portion of the connector is extending to the passivation layer, completely filled the opening, and disposed on the barrier layer.

According to some embodiments of the present disclosure, a second portion of the connector is protruding from a plane coplanar with the top surface of the passivation layer and disposed on the first portion of the connector.

According to some embodiments of the present disclosure, the passivation layer is made of polybenzoxazole, polyimide, benzocyclobutene, solder resist film, the like, or a combination thereof.

According to some embodiments of the present disclosure, the passivation layer is made of silicon nitride, silicon oxide, silicon oxynitride, silicon nitride oxide, phosphosilicate glass, borosilicate glass, boron-doped phosphosilicate glass, or a combination thereof.

According to some embodiments of the present disclosure, the barrier layer is made of aluminum fluoride, zinc oxide.

According to some embodiments of the present disclosure, the sidewall of the opening is substantially vertical or tapered.

According to some embodiments of the present disclosure, the connector is a solder joint.

According to some embodiments of the present disclosure, the solder joint is made of tin, silver, or copper.

According to some embodiments of the present disclosure, the semiconductor structure further comprises a molding material encapsulating the first substrate, the second substrate, the first semiconductor die, and the second semiconductor die.

According to some embodiments of the present disclosure, the molding material includes epoxy resin, PI, BCB, PBO, or PEEK.

Through the bonding structure of the present disclosure, the connectors can be arranged in the package structure with greater area, and the locations or sizes of the connectors can be chosen with greater flexibility. The connector layout can also be determined to comply with the design specification, and therefore the bonding performance can thus be improved.

The foregoing has outlined rather broadly the features and technical advantages of the present disclosure in order that the detailed description of the disclosure that follows may be better understood. Additional features and technical advantages of the disclosure are described hereinafter and form the subject of the claims of the disclosure. It should be appreciated by those skilled in the art that the concepts and specific embodiments disclosed may be utilized as a basis for modifying or designing other structures, or processes, for conducting the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description. It should be noted that, in accordance with the standard practice in the industry, various features are not drawn to scale. In fact, the dimensions of the various features may be arbitrarily increased or reduced for clarity of discussion.

FIGS. 1A and 1B are a cross-sectional view and a bottom view, respectively, of a semiconductor package structure, in accordance with some embodiments of the present disclosure.

FIGS. 2A and 2B are cross-sectional views of a semiconductor package structure, in accordance with various embodiments of the present disclosure.

FIGS. 3A to 3G are schematic cross-sectional views of intermediate stages of a method of forming a substrate, in accordance with some embodiments of the present disclosure.

FIGS. 4A to 4C are schematic cross-sectional views of intermediate stages of a method of forming a substrate, in accordance with some embodiments of the present disclosure.

FIGS. 5A to 5E are schematic cross-sectional views of intermediate stages of a method of forming a substrate, in accordance with some embodiments of the present disclosure.

FIGS. 6A to 6D are schematic cross-sectional views of intermediate stages of a method of forming a semiconductor die, in accordance with some embodiments of the present disclosure.

FIGS. 7A to 7H are schematic cross-sectional views of intermediate stages of a method of forming a semiconductor package structure, in accordance with some embodiments of the present disclosure.

FIGS. 8A to 8C are schematic cross-sectional views of intermediate stages of a method of forming a semiconductor package structure, in accordance with some embodiments of the present disclosure.

FIGS. 9A to 9E are schematic cross-sectional views of intermediate stages of a method of forming a semiconductor package structure, in accordance with some embodiments of the present disclosure.

FIG. 10 shows a schematic flowchart of a method of manufacturing a semiconductor package structure, in accordance with some embodiments of the present disclosure.

FIG. 11A shows a cross-sectional view of a semiconductor package structure, in accordance with various embodiments of the present disclosure.

FIG. 11B shows a schematic close-up cross-sectional view diagram of dotted area A as shown in FIG. 11B, in accordance with one embodiment of the present disclosure.

FIG. 12 shows a cross-sectional view of a semiconductor package structure, in accordance with various embodiments of the present disclosure.

FIG. 13 shows a cross-sectional view of a semiconductor package structure, in accordance with various embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers, or sections are not limited by these terms. Rather, these terms are merely used to distinguish one element, component, region, layer or section from another element, component, region, layer, or section. Thus, a first element, component, region, layer, or section discussed below could be termed a second element, component, region, layer, or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The terms “couple” or “connect” used throughout the present disclosure refers to physical or electrical linkage between two or more objects. These objects may also be referred to as being “coupled” or “connected” through exchange of data or information. These “coupled” or “connected” objects may be in direct contact in some cases or indirect contact through other intervening objects.

Embodiments of the present disclosure discuss a semiconductor package structure formed of a plurality of memory cells and a method of forming a semiconductor package structure. According to some embodiments of the present disclosure, at least two semiconductor dies are bonded together through a first substrate serving as a first interconnect structure. According to some embodiments of the present disclosure, the at least two semiconductor dies include memory dies or other suitable semiconductor dies. The at least two semiconductor dies are bonded to the first substrate in a vertical manner on two sides of the first substrate such that the package footprint can be minimized. Further, in order to minimize the device thickness of the semiconductor package, the first substrate is recessed to form a recess where one semiconductor die can be accommodated within the recess and bonded to the substrate. According to some embodiments of the present disclosure, the semiconductor package structure includes a plurality of connectors, which may be formed of solder bumps, configured to be electrically coupled to external devices or circuits. The available bonding area of the surface where the solder bumps are formed may be reduced due to the presence of the recess. As a result, the available bonding area may be less than the minimal requirement of the bonding area. The configuration, e.g., the locations, pitches, and sizes, of the solder bumps is constrained and may not comply with a design specification.

To address the abovementioned issues, a second substrate serving a second interconnect structure is proposed to aid in bonding the plurality of semiconductor dies, where the first substrate and at least one semiconductor die are bonded to a first side the second substrate. The solder bumps are bonded to a second side of the second substrate and electrically coupled to the plurality of semiconductor dies through the first substrate and the second substrate. As a result, the bonding area of the solder bumps is increased. The degree of freedom of allocating the solder bumps can thus be increased greatly. Therefore, the solder bumps can be arranged in a desirable manner for complying with the design specification without compromising the device performance.

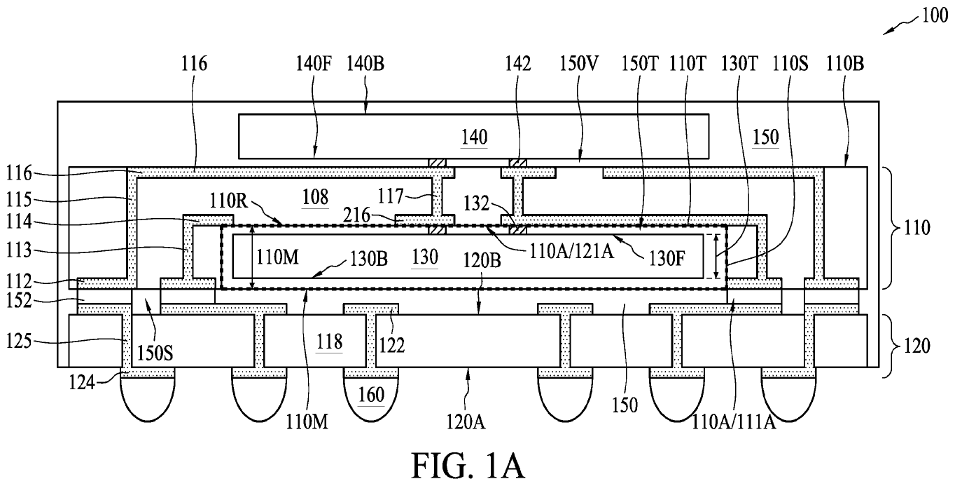

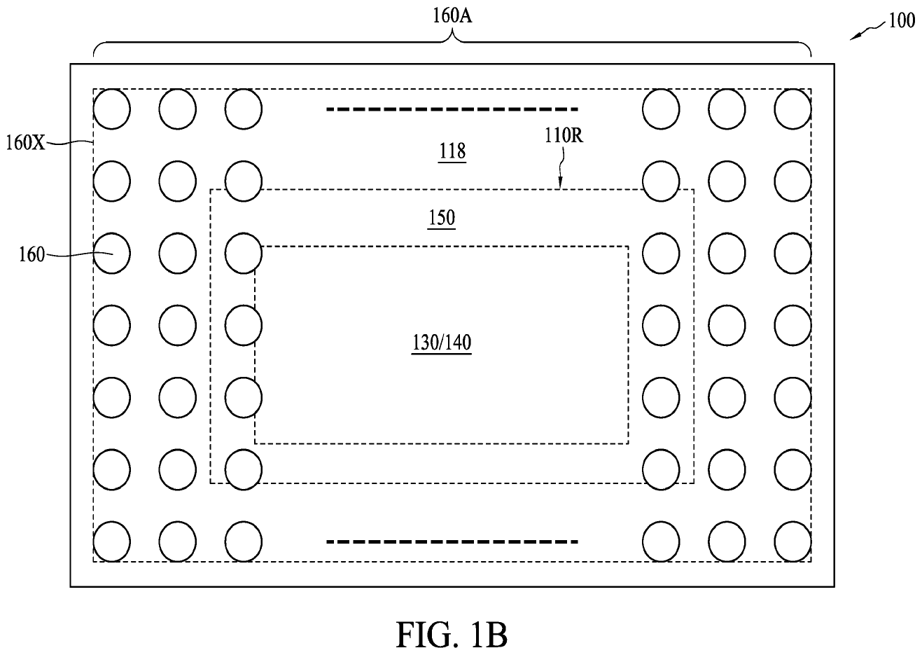

FIG. 1A is a cross-sectional view of a semiconductor package structure 100, in accordance with some embodiments of the present disclosure. According to some embodiments of the present disclosure, the semiconductor package structure 100 is a memory package. However, other types of semiconductor packages, such as an application specific integrated circuit (ASIC) package, a field-programmable gate array (FPGA) package, a processor package, a network integrated circuit (NIC) package, a microelectronic mechanical system (MEMS) package, a three-dimensional semiconductor IC package, a hybrid package, or other suitable types of packages. According to some embodiments of the present disclosure, the semiconductor package structure 100 includes a first substrate 110, a second substrate 120, a first semiconductor die 130, a second semiconductor die 140, a molding material 150, and a plurality of connectors 160.

According to some embodiments of the present disclosure, the first substrate 110 includes an interconnect structure electrically insulated by the electrically insulating material 108. According to some embodiments of the present disclosure, the interconnect structure of the first substrate 110 is constructed by a plurality of conductive line layers and a plurality of conductive via layers. The conductive line layers and the conductive via layers are collectively referred to herein as the metallization layers.

Each of the conductive line layers includes one or more conductive lines, e.g., conductive lines 112, 114, 116, arranged parallel to each other in a same conductive line layer, while each of the conductive via layers includes one or more conductive vias, e.g., conductive vias 113, 115 and 117, arranged in the same conductive via layer and configured to electrically couple one conductive line in the underlying conductive line layer to another conductive line in the overlying conductive line layer. According to some embodiments of the present disclosure, the components of the interconnect structure, i.e., the conductive lines 112, 114, 116 and the conductive vias 113, 115, 117, are formed of metallic materials, such as aluminum, copper, tungsten, titanium, titanium nitride, tantalum, tantalum nitride, alloys thereof, or other suitable conductive materials. According to some embodiments of the present disclosure, the conductive lines 112, 114, 116 and the conductive vias 113, 115, 117 includes a single layer structure or a multilayer structure, in which the multilayer structure is formed of at least one of a diffusion barrier layer, a seed layer and a filling layer.

According to some embodiments of the present disclosure, the conductive members of the conductive line layer and the conductive via layers are electrically insulated by an electrical insulating material 108. The electrical insulating material 108 may be formed of a dielectric material, such as silicon nitride, silicon oxide, silicon oxynitride, silicon carbide, high-k dielectric materials, or a polymeric material such as polymer, epoxy resin, polyimide (PI), benzocyclobutene (BCB), polybenzoxazole (PBO) or the like. According to some embodiments of the present disclosure, the electrical insulating material 108 includes a multilayer structure.

According to some other embodiments of the present disclosure, the first substrate 110 is a printed circuit board (PCB) substrate. An example PCB substrate may include a composite epoxy copper clad laminate, an epoxy fiberglass fabric copper clad laminate (FR-4), a paper phenolic copper clad laminate (XPC/FR-1), or the like. For example, the first substrate 110 may be formed of a copper-clad laminate structure (not separately shown), which includes a core layer, two prepreg layer on two sides of the core layer, and one or more circuit layers on the outer side of each of the prepreg layers to form a copper laminate. According to some embodiments of the present disclosure, the core layer is formed of an electrical insulating material, e.g., the fabric uses fiberglass cloth, and the core material uses bleached kraft paper. According to some embodiments of the present disclosure, an epoxy resin material is deposited on the fabric and the core material to form the prepreg layer. One or more copper foil layers are deposited over the prepreg layers, and one or more insulating layer formed of electric insulating materials or dielectric materials, e.g., epoxy resin, are arranged alternatively with the copper foil layers on the outer sides of the prepreg layers. The circuit layers are formed as the conductive line layers though patterning each of the copper foil layers. According to some embodiments of the present disclosure, the conductive via layers are formed through the insulating layers by via drilling and electroplating operations on the drilled vias. The conductive vias are formed to electrically connect the circuits in the overlying and underlying copper foil layers s.

According to some embodiments of the present disclosure, the second substrate 120 includes an interconnect structure electrically insulated by the electrically insulating material 118. According to some embodiments of the present disclosure, the interconnect structure of the second substrate 120 is constructed by one or more metallization layers, e.g., conductive line layers and conductive via layers. Each of the conductive line layers includes one or more conductive lines, e.g., conductive lines 122, 124, arranged parallel to each other in a same conductive line layer, while each of the conductive via layers includes one or more conductive vias, e.g., conductive vias 125, in the same conductive via layer and configured to electrically couple the one conductive line 122 in the underlying conductive line layer to another conductive line 124 in the overlying conductive line layer.

According to some embodiments of the present disclosure, the components of interconnect structure, e.g., the conductive lines 122, 124 and the conductive vias 125, are formed of metallic materials, such as aluminum, copper, tungsten, titanium, titanium nitride, tantalum, tantalum nitride, alloys thereof, or other suitable conductive materials. According to some embodiments of the present disclosure, the conductive lines 122, 124 and the conductive vias 125 includes a single layer structure or a multilayer structure. According to some embodiments of the present disclosure, the conductive vias extend through the thickness of the second substrate 120, and thus are also referred to herein as through-substrate vias (TSVs).

According to some embodiments of the present disclosure, the conductive members of the conductive line layers and the conductive via layers are electrically insulated by an electrical insulating material 118. The electrical insulating material 118 may be formed of a dielectric material, such as silicon nitride, silicon oxide, silicon oxynitride, silicon carbide, high-k dielectric materials, or a polymeric material such as polymer, epoxy resin, polyimide (PI), benzocyclobutene (BCB), polybenzoxazole (PBO), polyetheretherketone (PEEK) or the like. According to some embodiments of the present disclosure, the electrical insulating material 108 includes a multilayer structure.

According to some other embodiments of the present disclosure, at least one of the first substrate 110 and the second substrate 120 is a printed circuit board (PCB). An example PCB substrate may include a composite epoxy copper clad laminate, an epoxy fiberglass fabric copper clad laminate (FR-4), a paper phenolic copper clad laminate (XPC/FR-1), or the like. The second substrate 120 may include a copper clad laminate structure similar to that of the first substrate 110 as described above.

According to some embodiments of the present disclosure, each of the first semiconductor die 130 and the second semiconductor die 140 includes a memory die, a processor die, a network interface die, a MEMS die, or other suitable semiconductor dies. In the depicted example, at least one of the first semiconductor die 130 and the second semiconductor die 140 is a memory die, which is formed of one or more memory arrays and control circuits configured to control read/write access of the memory arrays.

According to some embodiments of the present disclosure, the first semiconductor die 130 includes a front side 130F facing a first side 110A of the first substrate 110 and a backside 130B facing a second side 120B of the second substrate 120. Similarly, according to some embodiments of the present disclosure, the second semiconductor die 140 includes a front side 140F facing the second side 110B of the first substrate 110 or the second substrate 120, and a backside 140B facing away from the first substrate 110 or the second substrate 120.

According to some embodiments of the present disclosure, the first substrate 110 includes a recess 110R formed on the first side 110A of the first substrate 110. The recess 110R may be arranged in the center of the first side 110A. As a result, the first side 110A includes a recess surface 121A, which is referred to herein as an upper surface 121A of the first side 110A. According to some embodiments of the present disclosure, the recess 110R includes a rectangular shape from a bottom-view perspective (see FIG. 1B). According to some embodiments of the present disclosure, the surface 121A of the recess 110R includes straight sidewalls 110S and substantially flat bottom (upper) surface 110T connected to the sidewalls 110S. The height of the sidewalls 110S or the depth of the recess 110R may be in a range between about 50 μm and about 400 μm. According to some embodiments of the present disclosure, an area ratio between the recess 110R and the entire first side 110A is in a range between about 20% and about 80%.

According to some embodiments of the present disclosure, the backside 130B of the first semiconductor die 130 is higher than the bottom surface or a lower surface 111A of the first side 110A of the first substrate 110. However, in some other embodiments, the backside 130B of the first semiconductor die 130 is lower than (i.e., extending beyond) or substantially level with the bottom surface 111A or the lower surface 111A of the first side 110A of the first substrate 110. According to some embodiments of the present disclosure, the thickness 130T of the first semiconductor die 130 is greater than, substantially equal to, or less than the depth or height 110M of the recess 110R. Through the arrangement of the first semiconductor die 130 within the recess 110R of the first substrate 110, the thickness of the bonded structure of the first substrate 110 and the first semiconductor die 130 is significantly reduced, and the transmission distance between the first substrate 110 and the first semiconductor die 130 is decreased due to the recess 110R. The electrical performance of the semiconductor package structure 100 is therefore improved.

According to some embodiments of the present disclosure, the first semiconductor die 130 includes one or more connectors 132 formed on the upper surface 121A of the first side 110A and electrically coupling the first semiconductor die 130 to the first side 110A of the first substrate 110, e.g., the conductive lines 216 of the first substrate 110. Likewise, according to some embodiments of the present disclosure, the second semiconductor die 140 includes one or more connectors 142 formed on the front side 140F and electrically coupling the second semiconductor die 140 to the second side 110B of the first substrate 110, e.g., the conductive lines 116 of the first substrate 110. The connectors 132 or 142 may be conductive pads serving as bond pads, and formed of a conductive material, such as copper, aluminum, tungsten, silver, gold, titanium, titanium nitride, tantalum, tantalum nitride, alloys thereof, of the like.

According to some embodiments of the present disclosure, the molding material 150 encapsulates the first substrate 110, the second substrate 120, the first semiconductor die 130 and the second semiconductor die 140. According to some embodiments of the present disclosure, the molding material 150 fills a space 150T between the first substrate 110 and the first semiconductor die 130. According to some embodiments of the present disclosure, the molding material 150 fills a space 150V between the first substrate 110 and the second semiconductor die 140. According to some embodiments of the present disclosure, the molding material 150 includes a dielectric material, e.g., a polymeric material such as epoxy resin, PI, BCB, PBO, or PEEK, or the like.

According to some embodiments of the present disclosure, the connectors 160 are formed on the first side 120A of the second substrate 120. FIG. 1B is a bottom view of a semiconductor package structure 100, in accordance with some embodiments of the present disclosure. As shown in FIG. 1A and FIG. 1B, the connectors 160 are formed to overlap the lower surface 111A and the upper surface 121A of the first substrate 110, i.e., the connectors 160 at least overlap the recess 110R from a bottom-view or top-view perspective. According to some embodiments of the present disclosure, the connectors 160 form an array that occupies an area greater than the area of the recess 110R projected on the first substrate 110. Through the arrangement of the connectors 160 on the first side 120A of the second substrate 120, the available bonding area for the connectors 160 are increased accordingly, and the design specification for arranging the locations of the specific input/output terminals of the semiconductor package structure 100 can be achieved easily through the connectors 160.

According to some embodiments of the present disclosure, the connector 160 is a solder material formed of lead-based materials, such as Sn, Pb, Ni, Au, Ag, Cu, Bi, combinations thereof, or mixtures of other electrically conductive materials. According to some other embodiments, the connector 160 includes a lead-free material. According to some embodiments of the present disclosure, the connector 160 includes a spherical shape. However, other shapes of the connector 160 may be also possible. According to some embodiments of the present disclosure, the connectors 160 are configured as contact bumps such as controlled collapse chip connection (C4) bumps, ball grid array bumps, or microbumps.

According to some embodiments of the present disclosure, the semiconductor package structure 100 further includes bonding members 152 between the first substrate 110 and the second substrate 120 and configured to bond the first substrate 110 to the second substrate 120. According to some embodiments of the present disclosure, the bonding members 152 bonds the conductive lines 112 of the first substrate 110 to the corresponding conductive lines 122 of the second substrate 120.

According to some embodiments of the present disclosure, the bonding members 152 includes a metallic material such as copper, tungsten, or other suitable metals. According to some embodiments of the present disclosure, the bonding members 152 is a solder material formed of lead-based materials, such as Sn, Pb, Ni, Au, Ag, Cu, Bi, combinations thereof, or mixtures of other electrically conductive material. According to some other embodiments, the bonding member 152 includes a lead-free material. According to some embodiments of the present disclosure, the bonding member 152 is configured as a conductive bump, a conductive post, a conductive pillar, or the like.

According to some embodiments of the present disclosure, the first semiconductor die 130 is bonded to the first substrate 110 through flip-chip bonding, in which the front side 130F faces the first side 110A (or the upper surface 121A) of the first substrate 110. Such bonding can reduce the transmission length between the first substrate 110 and the first semiconductor die 130. However, since the entire backside 130B of the first semiconductor die 130 is covered by the molding material 150, the first semiconductor die 130 does not include any bond pads on the backside 130B. As a result, the recessed area of first side 110A due to the recess 110R cannot be used in forming the connectors between the first substrate 110 and external circuits. The available bonding area left may not be sufficient with respect to a specification of a specific input/output terminal configuration. However, the introduction of the second substrate 120 provides an additional bonding area on the first side 120A as compared to the first side 110A of the first substrate 110. As a result, the connectors 160 formed on the first side 120A of the second substrate 120 can adapt to the specific input/output terminal configuration, and the bonding requirement of the semiconductor package structure 100 can be fulfilled without compromising the performance of the semiconductor package structure 100.

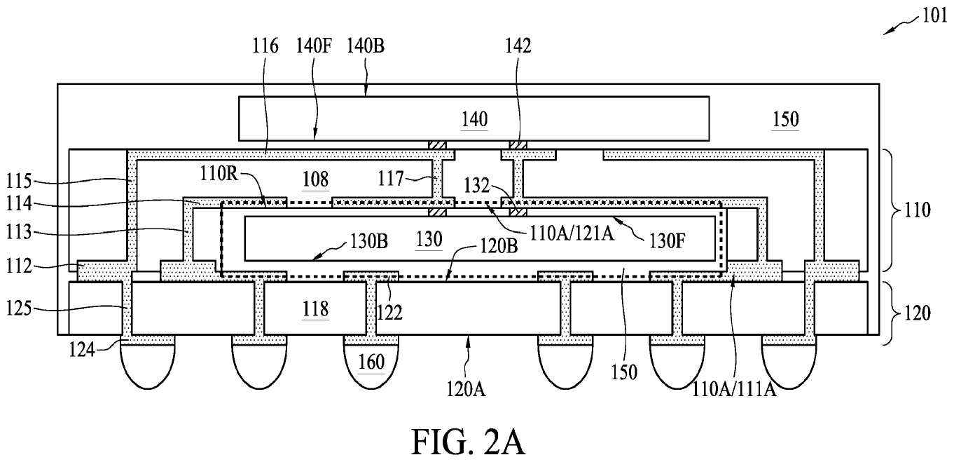

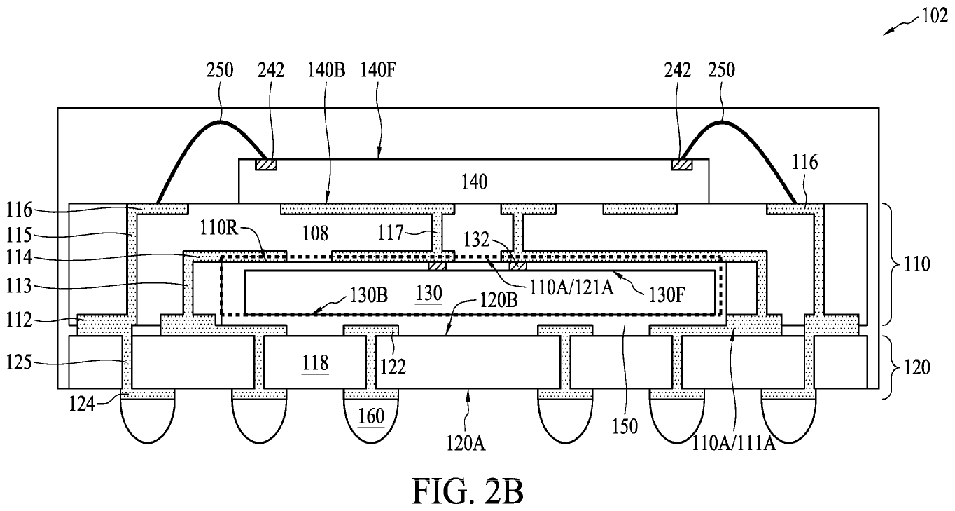

FIG. 2A is a cross-sectional view of a semiconductor package structure 101, in accordance with various embodiments of the present disclosure. The semiconductor package structure 101 is similar to the semiconductor package structure 100 in many aspects, and thus these similar features will not be repeated herein. The semiconductor package structure 101 differs in the semiconductor package structure 100 mainly in that the first substrate 110 of the semiconductor package structure 101 is directly bonded to the second substrate 120 without the bonding members 152. In other words, according to some embodiments, the conductive lines 112 of the first substrate 110 are in physical contact with the conductive lines 122 of the second substrate 120 through formation of metallic bonds between the conductive lines 112 and the conductive lines 122. According to some embodiments of the present disclosure, the conductive lines 112 and the conductive line 122 are formed of the same metal, e.g., copper, for facilitating the formation of the metallic bonds.

FIG. 2B is a cross-sectional view of a semiconductor package structure 102, in accordance with various embodiments of the present disclosure. The semiconductor package structure 102 is similar to the semiconductor package structure 101 in many aspects, and thus these similar features will not be repeated herein. The semiconductor package structure 102 differs in the semiconductor package structure 101 mainly in that the second semiconductor die 140 of the semiconductor package structure 101 is bonded to the first substrate 110 through conductive lines (or conductive traces) 250 through wire bonding and via conductive pads 242 formed on the front side 140F of the second semiconductor die 140. Furthermore, the front side 140F of the second semiconductor die 140 is facing away from the first substrate 110. According to some embodiments of the present disclosure, the conductive line 250 is formed of a conductive material, such as copper, aluminum, silver, gold, tungsten, alloys thereof, or the like. According to some embodiments of the present disclosure, the conductive line 250 is bonded to the conductive line 116 of the first substrate 110. The conductive line 250 is also encapsulated by the molding material 150 along with the first substrate 110. Therefore, the integrity and robustness of the bonding performance of the wire bonding through the conductive lines 250 can be maintained.

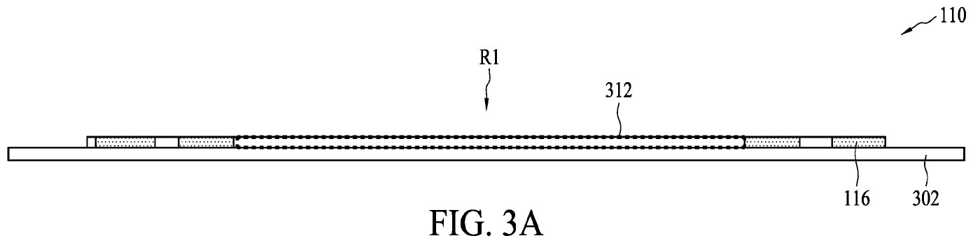

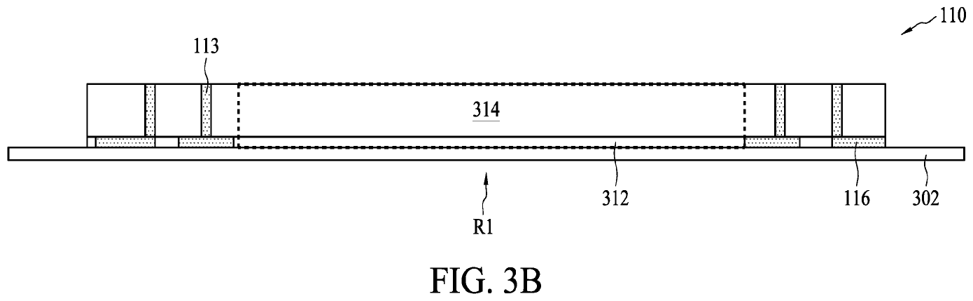

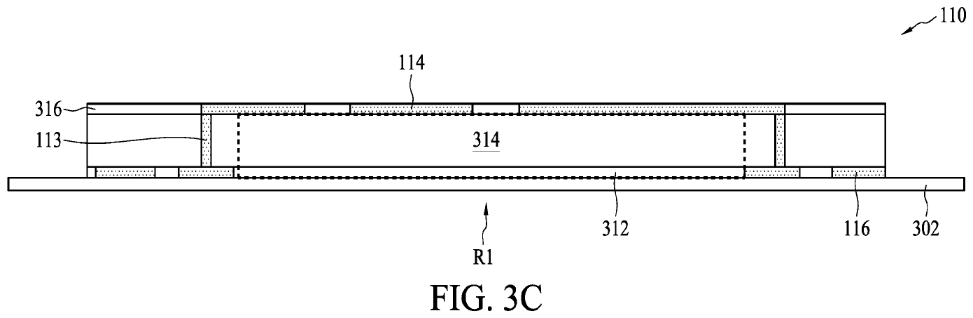

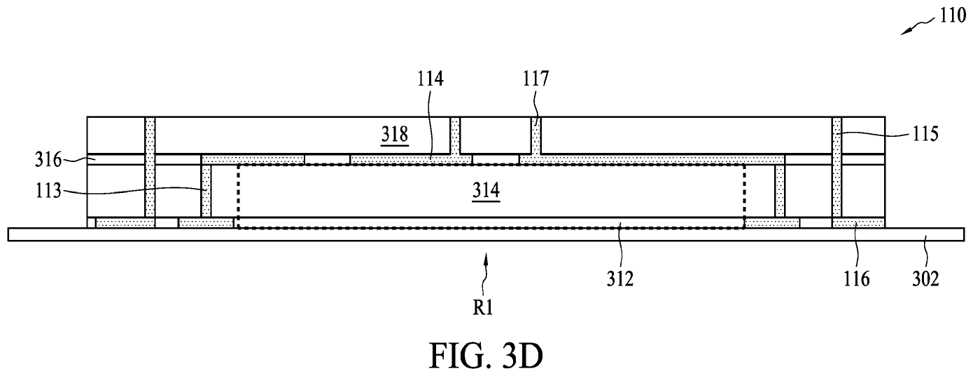

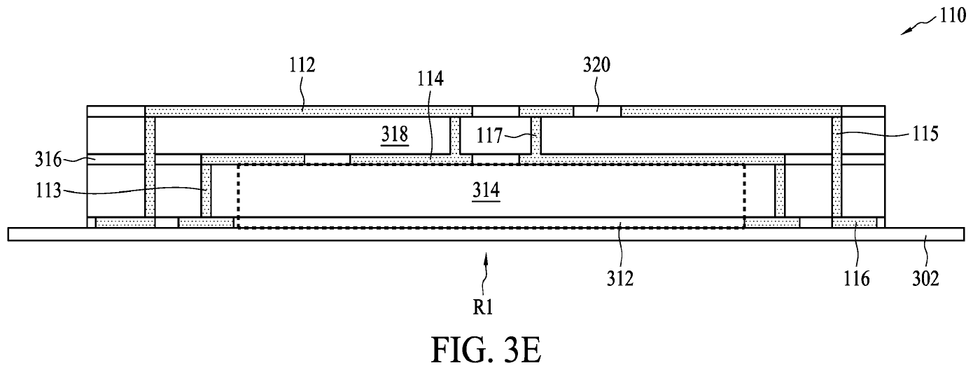

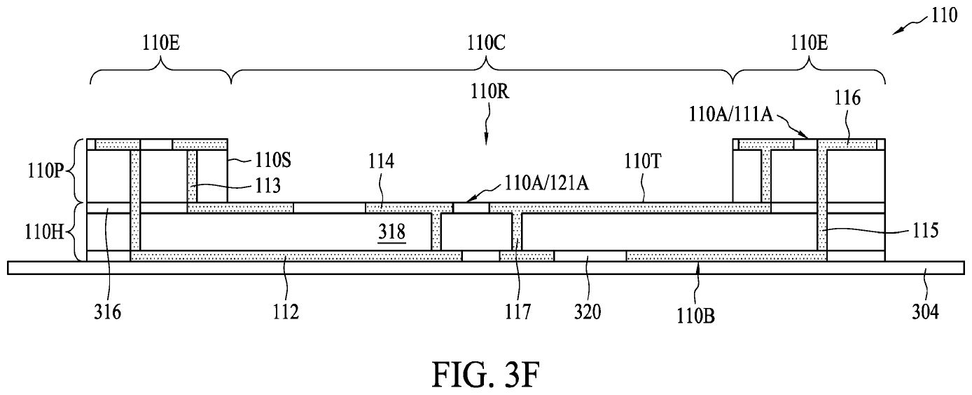

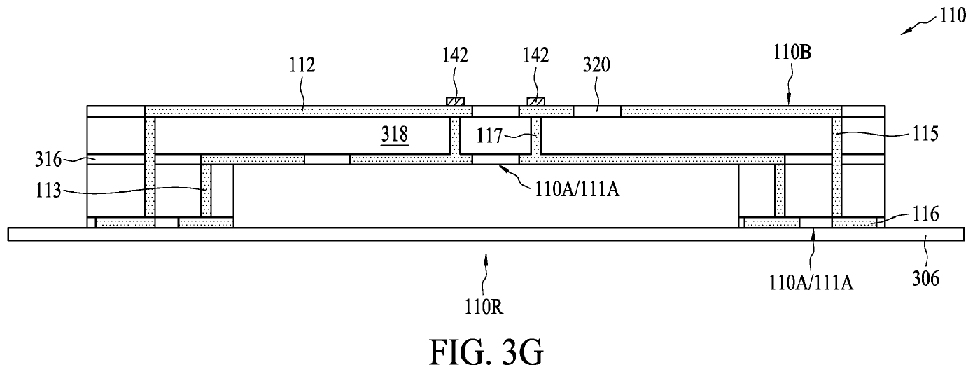

FIGS. 3A to 3G are schematic cross-sectional views of intermediate stages of a method 300 of forming the interconnect structure of the first substrate 110, in accordance with some embodiments of the present disclosure. It is understood that additional steps can be provided before, during, and after the steps shown by FIGS. 3A to 3G, and some of the steps described below can be replaced or eliminated in additional embodiments of the method 300. The order of the steps may be interchangeable.

Referring to FIG. 3A, a substrate 302 is formed, provided, or received. According to some embodiments of the present disclosure, the substrate 302 is a carrier substrate. The substrate 302 may include a semiconductor material, such as bulk silicon or other suitable semiconductor materials. According to some other embodiments, the substrate 302 is formed of glass, ceramics, or other substrate materials.

According to some embodiments of the present disclosure, a first dielectric layer 312 is deposited over the substrate 302. Referring to FIG. 1A and FIG. 3A, the first dielectric layer 312 may be a topmost sublayer of the first substrate 110. The first dielectric layer 312 may include silicon nitride, silicon oxide, silicon oxynitride, silicon carbide, or other dielectric materials. The first dielectric layer 312 may be deposited on the substrate 302 by chemical vapor deposition (CVD), physical vapor deposition (PVD), atomic layer deposition (ALD), spin-on coating, or other deposition methods. According to some embodiments of the present disclosure, a patterning operation is performed on the first dielectric layer 312. The patterning operation may include photolithography and etching operations. As an example, photolithography operation, a photoresist film is deposited over the first dielectric layer 312. An exposure operation is performed to transfer a circuit pattern to the photoresist film through a patterned reticle or photomask. The exposed photoresist film is developed such that unwanted portions of the photoresist film are removed to thereby leave the pattern of the circuit on the photoresist film. The etching operation is subsequently performed to etch the first dielectric layer 312 with the photoresist film serving as the etching mask. According to some embodiments of the present disclosure, the etching operation may include a dry etch, a wet etch, a combination thereof, e.g., reactive ion etch (RIE), or the like. Through the etching operation, openings are formed through the first dielectric layer 312.

A deposition operation may be formed to fill a conductive material in the openings. The conductive material may include copper, aluminum, tungsten, silver, gold, titanium, titanium nitride, tantalum, tantalum nitride, alloys thereof, of the like. The deposition operation may include CVD, PVD, ALD, plating, or other suitable deposition methods. According to some embodiments of the present disclosure, a planarization operation is performed to remove the excess material of the conductive materials over the surface of the first dielectric layer 312. The planarization operation may include chemical mechanical polishing (CMP), mechanical grinding, or other suitable polishing operations. The conductive lines 116 are therefore formed in the first dielectric layer 312. Referring to FIG. 1A and FIG. 3A, the first dielectric layer 312 and the conductive lines 116 in the first dielectric layer 312 may be collectively referred to as the first metallization layer of the first substrate 110.

According to some embodiments, a region R1 in a center of the first dielectric layer 312 is reserved and not used for depositing the conductive lines 116. The region R1 is free of any conductive members of the interconnect structure and is reserved to be removed for forming the recess 110R shown in FIGS. 1A, 1B, 2A and 2B.

Referring to FIG. 3B, a second dielectric layer 314 is formed over the first dielectric layer 312 and the conductive lines 116. The second dielectric layer 314 is patterned, in which the conductive vias 113 are formed through the second dielectric layer 314 and electrically coupled to the conductive lines 116. The materials, configurations, and method of formation for the second dielectric layer 314 and the conductive vias 113 are similar to those of the first dielectric layer 312 and the conductive lines 116. Referring to FIG. 1A and FIG. 3B, the second dielectric layer 314 and the conductive vias 113 in the second dielectric layer 314 may be collectively referred to as the second metallization layer of the first substrate 110.

According to some embodiments, the space for the region R1 in the first dielectric layer 312 extends through the second dielectric layer 314 and not used for the conductive vias 113. The region R1 is free of any conductive members of the interconnect structure of the first substrate 110 shown in FIGS. 1A, 1B, 2A and 2B.

Referring to FIG. 3C, a third dielectric layer 316 is formed over the second dielectric layer 314 and the conductive vias 113. The third dielectric layer 316 is patterned, in which the conductive lines 114 are formed in the third dielectric layer 316 and electrically coupled to the conductive vias 113. The materials, configurations, and method of formation for the third dielectric layer 316 and the conductive lines 116 are similar to those of the first dielectric layer 312 and the conductive lines 116. Referring to FIG. 1A and FIG. 3C, the third dielectric layer 316 and the conductive lines 114 in the third dielectric layer 316 may be collectively referred to as the third metallization layer of the first substrate 110.

Referring to FIG. 3D, a fourth dielectric layer 318 is formed over the third dielectric layer 316 and the conductive lines 116. The fourth dielectric layer 318 is patterned, in which the conductive vias 117 are formed through the fourth dielectric layer 318 and electrically coupled to the conductive lines 116.

According to some embodiments of the present disclosure, vias are formed through the dielectric layers 318, 316, 314 to expose the conductive lines 116 in the first dielectric layer 312. One or more conductive materials are deposited in the vias to form conductive vias 115. The conductive vias 115 may be formed exposed through the fourth dielectric layer 318 and configured to electrically couple the conductive lines 116 to the conductive members in the overlying layers. The materials, configurations, and method of formation for the fourth dielectric layer 318 and the conductive vias 117, 115 are similar to those of the first dielectric layer 312 and the conductive lines 116. Referring to FIG. 1A and FIG. 3D, the fourth dielectric layer 318 and the conductive vias 117, 115 in the fourth dielectric layer 318 may be collectively referred to as the fourth metallization layer of the first substrate 110.

Referring to FIG. 3E, a fifth dielectric layer 320 is formed over the fourth dielectric layer 318 and the conductive vias 117. The fifth dielectric layer 320 is patterned, in which the conductive lines 112 are formed in the fifth dielectric layer 320 and electrically coupled to the conductive vias 117 and 115. The materials, configurations, and method of formation for the fifth dielectric layer 320 and the conductive lines 112 are similar to those of the first dielectric layer 312 and the conductive lines 116. Referring to FIG. 1A and FIG. 3E, the fifth dielectric layer 320 and the conductive lines 112 in the fifth dielectric layer 320 may be collectively referred to as the fifth metallization layer of the first substrate 110.

According to some embodiments of the present disclosure, the abovementioned dielectric layers 312, 314, 316, 318 and 329 construct the main body of the first substrate 110, and the conductive lines 112, 114, 116 and the conductive vias 113, 117 are electrically interconnected to form the interconnect structure in the first substrate 110. The interconnect structure is configured to electrically couple the first semiconductor die 130 and the second semiconductor die 140 to the second substrate 120. Although FIGS. 1A, 2A, 2B and 3A through 3E illustrate five metallization layers of the first substrate 110, they are shown for illustrative purposes only. Other numbers of metallization layers of the first substrate 110 and other configurations of conductive lines and conductive vias are also with the contemplated scope of the present disclosure.

Subsequently, the first substrate 110 is flipped and arranged on another substrate 304, as shown in FIG. 3F. According to some embodiments of the present disclosure, the substrate 304 is a carrier substrate. The substrate 304 may include a semiconductor material, such as bulk silicon or other suitable semiconductor materials. According to some other embodiments, the substrate 304 is formed of glass, ceramics, or other substrate materials. According to some embodiments of the present disclosure, the substrate 304 includes a material similar to the material of the substrate 302.

The substrate 302 is removed from the first substrate 110. According to some embodiments, the substrate 302 is removed by an etching operation. According to some embodiments, a release film (not separately shown) is bonded between the substrate 302 and the first dielectric layer 312 of the first substrate 110. When the substrate 302 is removed from the first substrate 110, the release film is detached from the surface of the first dielectric layer 312 by heat or ultraviolet light and therefore removed from the first substrate 110 with the substrate 302.

According to some embodiments of the embodiments, the space of the recess 110R is recessed from the first side 110A by an etching operation, e.g., a dry etch, a wet etch, an RIE, or the like. The etching operation may stop at the conductive lines 114, and thus the conductive lines 114 are exposed by the etching operation. Through the etching operation, the first side 110A of the first substrate 110 includes a stepped shape, which is formed of an upper surface 121A and a lower surface 111A when viewed upside-down (the orientation of FIG. 1A). According to some embodiments, the sidewalls 110S of the recess 110R may be straight, slanted, or include a curved shape.

According to some embodiments of the present disclosure, the first substrate 110 including the recess 110R includes a horizontal portion 110H and a protrusion portion 110P, in which the protrusion portion 110P protrudes from a peripheral region 110E of the horizontal portion 110H and defines the recess 110R. According to some embodiments of the present disclosure, the third dielectric layer 316, the fourth dielectric layer 318 and the fifth dielectric layer 320 along with the conductive lines 112, 114 and the conductive vias 117 (may further include part of the conductive vias 115) form the horizontal portion 110H, while the first dielectric layer 312, the second dielectric layer 314 along with the conductive lines 116 and the conductive vias 113 (may further include part of the conductive vias 115) form the protrusion portion 110P. According to some embodiments of the present embodiments, the depth of the recess 110R is substantially equal to the height of the protrusion portion 110P.

Referring to FIG. 3G, the first substrate 110 is flipped again and arranged on another substrate 306. According to some embodiments of the present disclosure, the substrate 306 is a carrier substrate. The substrate 306 may include a semiconductor material, such as bulk silicon or other suitable semiconductor materials. According to some other embodiments, the substrate 306 is formed of glass, ceramics, or other substrate materials. According to some embodiments of the present disclosure, the substrate 306 includes a material similar to the material of the substrate 302 or 304.

According to some embodiments of the present disclosure, a plurality of conductive pads 142 are formed on the second side 110B of the first substrate 110. The conductive pads 142 serve as bonding pads to bond the first substrate 110 to other semiconductor devices, e.g., the second semiconductor die 140. The conductive pads 142 may be bonded to the conductive lines 112. The conductive pads 142 may be formed by CVD, PVD, ALD, plating, or other suitable deposition operations.

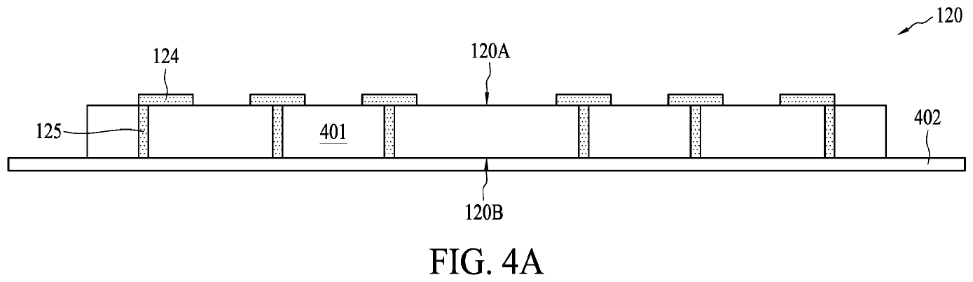

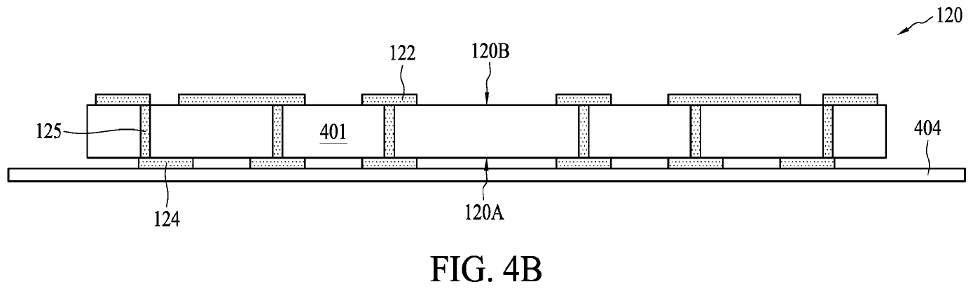

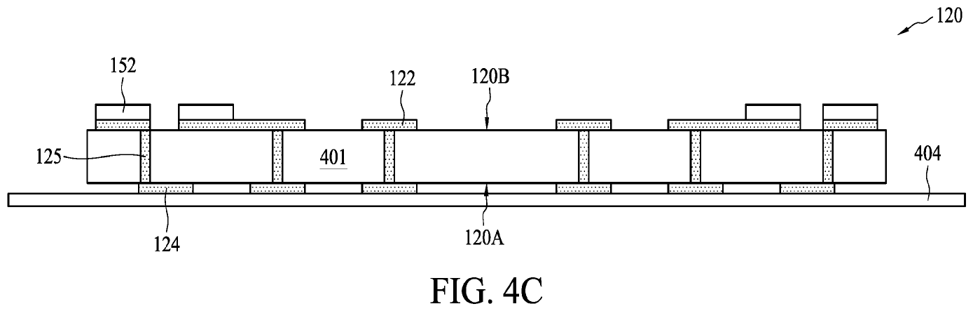

FIGS. 4A to 4C are schematic cross-sectional views of intermediate stages of a method 400 of forming the second substrate 120, in accordance with some embodiments of the present disclosure. It is understood that additional steps can be provided before, during, and after the steps shown by FIGS. 4A to 4C, and some of the steps described below can be replaced or eliminated in additional embodiments of the method 400. The order of the steps may be interchangeable.

Referring to FIG. 4A, a substrate 402 is provided or received. According to some embodiments of the present disclosure, the substrate 402 is a carrier substrate. The substrate 402 may include a semiconductor material, such as bulk silicon or other suitable semiconductor materials. According to some other embodiments, the substrate 402 is formed of glass, ceramics, or other substrate materials.

According to some embodiments of the present disclosure, a substrate 401 is provided or received. According to some embodiments, the substrate 401 includes a semiconductor material, such as bulk silicon or other suitable semiconductor materials. According to some embodiments, the substrate 401 is a semiconductor wafer and in a circular or rectangular shape.

According to some embodiments of the present disclosure, a patterning operation is performed on the substrate 401. The patterning operation may include photolithography and etching operations. As an example, photolithography operation, a photoresist film is deposited over the substrate 401. An exposure operation is performed to transfer a circuit pattern to the photoresist film through a patterned reticle or photomask. The exposed photoresist film is developed such that unwanted portions of the photoresist film are removed to thereby leave the pattern of the circuit on the photoresist film. The etching operation is subsequently performed to etch the substrate 401 with the photoresist film serving as the etching mask.

According to some embodiments of the present disclosure, the etching operation may include a dry etch, a wet etch, a combination thereof, e.g., reactive ion etch (RIE), or the like. Through the etching operation, vias are formed through the substrate 401. A deposition operation may be formed to fill a conductive material in the vias. The conductive material may include copper, aluminum, tungsten, silver, gold, titanium, titanium nitride, tantalum, tantalum nitride, alloys thereof, of the like. The deposition operation may include CVD, PVD, ALD, plating, or other suitable deposition methods. According to some embodiments of the present disclosure, a planarization operation is performed to remove the excess material of the conductive materials over the surface of the substrate 401. The planarization operation may include CMP, mechanical grinding, or other suitable polishing operations. The conductive vias 125 are therefore formed through the substrate 401 as the TSVs.

A plurality of conductive lines 124 are formed on the first side 120A of the second substrate 120 and electrically coupled to the conductive vias 125. An example process of forming the conductive lines 124 may include deposition of a blanket conductive material on the first side 120A of the second substrate 120, followed by a patterning operation on the blanket conductive material. The patterning operation of the conductive lines 124 may be similar to that of the first dielectric layer 312 discussed previously.

Subsequently, the second substrate 120 is flipped and arranged on another substrate 404, as shown in FIG. 4B. According to some embodiments of the present disclosure, the substrate 404 is a carrier substrate. The substrate 404 may include a semiconductor material, such as bulk silicon or other suitable semiconductor materials. According to some other embodiments, the substrate 404 is formed of glass, ceramics, or other substrate materials. According to some embodiments of the present disclosure, the substrate 404 includes a material similar to the material of the substrate 402.

The substrate 402 is removed from the second substrate 120. According to some embodiments, the substrate 402 is removed by an etching operation. According to some embodiments, a release film (not separately shown) is bonded between the substrate 402 and the second substrate 120. When the substrate 402 is removed from the first substrate 110, the release film is detached from the surface of the second substrate 120 by heat or ultraviolet light and therefore removed from the second substrate 120 with the substrate 402.

A plurality of conductive lines 122 are formed on the second side 120B of the second substrate 120 and electrically coupled to the conductive vias 125. The materials, configurations, and method of formation for the conductive lines 122 are similar to those of the conductive lines 124. The conductive lines 122, 124 and the conductive vias 125 are electrically interconnected to form the interconnect structure of the second substrate 120. Although FIGS. 1A, 2A, 2B and 4A through 4C illustrate only two conductive line layers of the second substrate 120, they are shown for illustrative purposes only. One or more dielectric layers, e.g., the dielectric layers 312, 314, 316, 318, 320 of the first substrate 110, and other configurations of conductive lines and conductive vias are also with the contemplated scope of the present disclosure, e.g., the conductive lines 112, 114, 116 and the conductive vias 113, 117, can be incorporated into the second substrate 120 to generate a multilayer structure with multiple metallization layers in the second substrate 120.

Referring to FIG. 4C, a plurality of bonding members 152 are formed on the surface of the conductive lines 122. The bonding members 152 may be deposited on the conductive lines 122 by CVD, PVD, ALD, plating, or other suitable deposition methods. Bonding members 152 may be alternatively formed by ball dropping, solder pasting, stencil printing or any other suitable operations. According to some embodiments of the present disclosure, the bonding members 152 are not overlapped with the recess 110R from a top-view perspective.

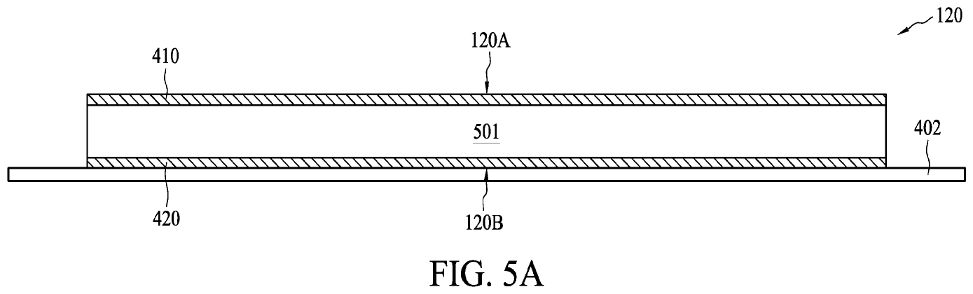

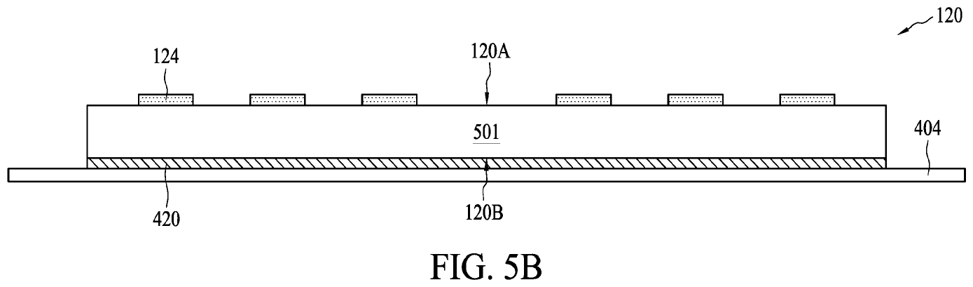

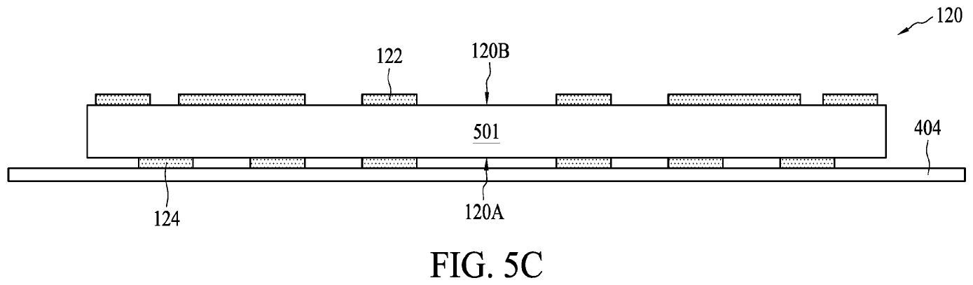

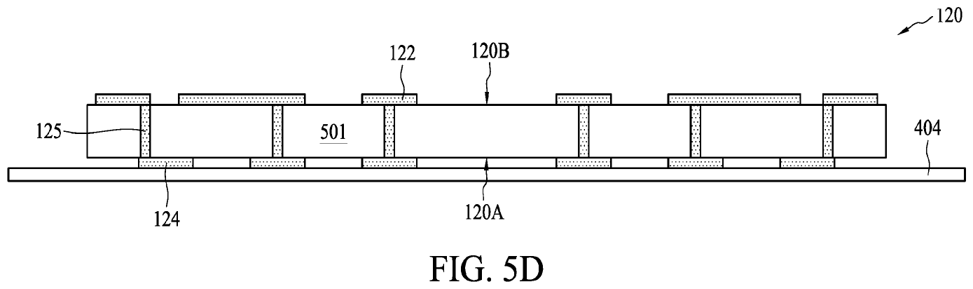

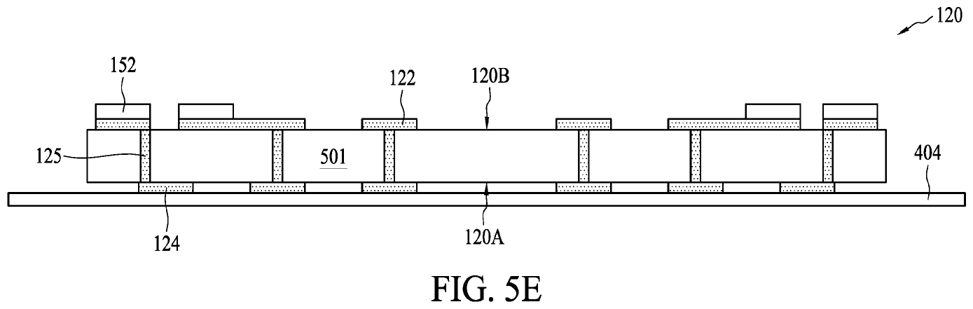

FIGS. 5A to 5E are schematic cross-sectional views of intermediate stages of a method 500 of forming the second substrate 120, in accordance with some embodiments of the present disclosure. It is understood that additional steps can be provided before, during, and after the steps shown by FIGS. 5A to 5E, and some of the steps described below can be replaced or eliminated in additional embodiments of the method 500. The order of the steps may be interchangeable.

Referring to FIG. 5A, a laminate structure for the second substrate 120 is provided or received on the substrate 402. According to some embodiments of the present disclosure, the laminate structure includes a copper clad laminate structure and has a composite core layer 501 and two copper foil layers 410, 420 on two sides of the composite core layer 501. According to some embodiments of the present disclosure, the composite core layer 501 includes a core layer, two prepreg layer on two sides of the core layer. The copper foil layers 410, 420 are formed on the outer side of each of the prepreg layer to form a copper laminate. According to some embodiments of the present disclosure, the core layer is formed of an electrical insulating material, e.g., the fabric uses fiberglass cloth and core material uses bleached kraft paper. An epoxy resin material is deposited on the fabric and the core material to form the prepreg layer. According to some embodiments of the present disclosure, the copper foil layers 410, 420 are replaced by other metals, such as aluminum, tungsten, or the like.

Referring to FIG. 5B, a patterning operation is performed on the copper foil layer 410 to form a plurality of conductive lines 124. The patterning operation may include photolithography and etching operations. According to some embodiments of the present disclosure, the etching operation includes a dry etch, a wet etch, an RIE, or the like.

Referring to FIG. 5C, the second substrate 120 is flipped and arranged on the substrate 404. According to some embodiments of the present disclosure, the substrate 404 is a carrier substrate. The substrate 402 is removed from the second substrate 120. According to some embodiments of the present disclosure, a patterning operation is performed on the copper foil layer 420 to form a plurality of conductive lines 122. The patterning operation may include photolithography and etching operations. According to some embodiments of the present disclosure, the etching operation includes a dry etch, a wet etch, an RIE, or the like.

FIG. 5D illustrates the formation of the conductive vias 125 through the composite core layer 501. According to some embodiments of the present disclosure, a drilling operation is performed to form vias through the composite core layer 501 and the copper foil layers 410, 420. A deposition operation may be formed to deposit a conductive material on the sidewalls of the vias. The conductive material may include copper, aluminum, tungsten, silver, gold, titanium, titanium nitride, tantalum, tantalum nitride, alloys thereof, of the like. The deposition operation may include CVD, PVD, ALD, plating, or other suitable deposition methods. The conductive vias 125 are therefore formed through the composite core layer 501 and serve as the TSVs to electrically couple the conductive lines 122 to the corresponding conductive lines 124.

Referring to FIG. 5E, a plurality of bonding members 152 are formed on the surface of the conductive lines 122. The bonding members 152 may be deposited on the conductive lines 122 by CVD, PVD, ALD, plating, ball dropping, solder pasting, stencil printing or other suitable deposition methods. According to some embodiments of the present disclosure, the bonding members 152 are not overlapped with the recess 110R from a top-view perspective.

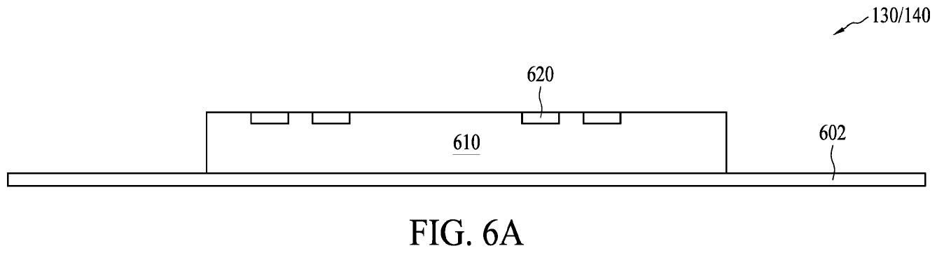

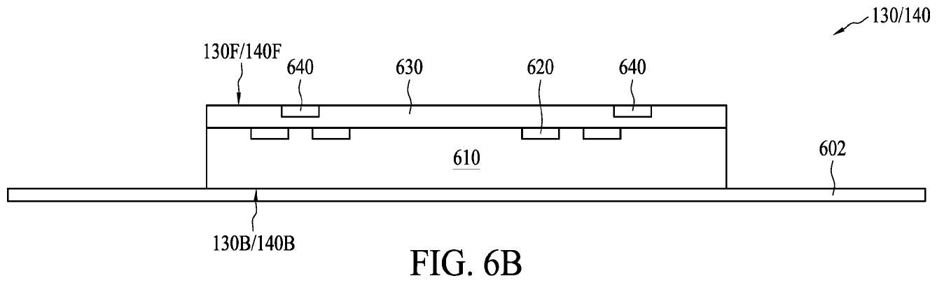

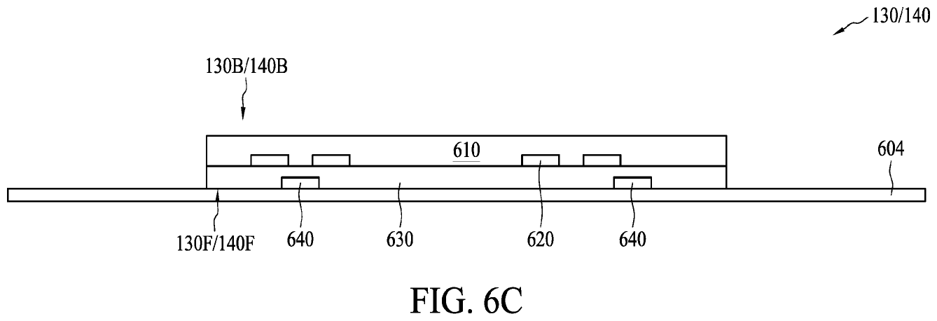

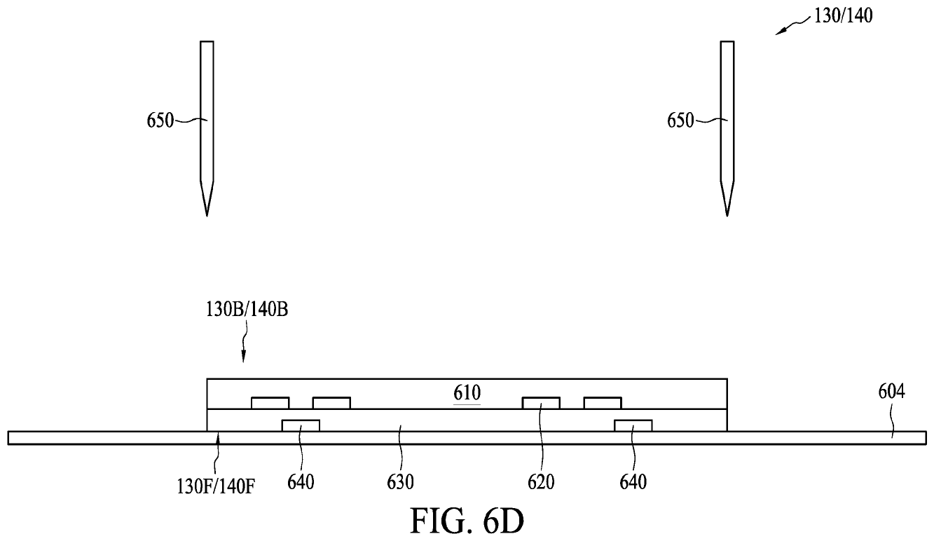

FIGS. 6A to 6D are schematic cross-sectional views of intermediate stages of a method 600 of forming the first semiconductor die 130 or the second semiconductor die 140, in accordance with some embodiments of the present disclosure. It is understood that additional steps can be provided before, during, and after the steps shown by FIGS. 6A to 6D, and some of the steps described below can be replaced or eliminated in additional embodiments of the method 600. The order of the steps may be interchangeable.

Referring to FIG. 6A, a substrate 610 is provided or formed on a substrate 602. According to some embodiments of the present disclosure, the substrate 602 is a carrier substrate. The substrate 602 may include a semiconductor material, such as bulk silicon or other suitable semiconductor materials. In some other embodiments, the substrate 602 is formed of glass, ceramics, or other substrate materials.

According to some embodiments of the present disclosure, the substrates 610 includes semiconductor material such as bulk silicon. In some embodiments, the substrate 610 includes other semiconductor materials, such as silicon germanium, silicon carbide, gallium arsenide, or the like. According to some embodiments of the present disclosure, the substrate 610 is a P-type semiconductive substrate (acceptor type). According to some other embodiments of the present disclosure, an N-type semiconductive substrate (donor type) 610 can be used. Alternatively, the substrate 610 includes another elementary semiconductor, such as germanium; a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. According to some embodiments of the present disclosure, the substrate 610 includes a semiconductor-on-insulator (SOI) substrate. According to some embodiments of the present disclosure, the substrate 610 include a doped epitaxial layer, a gradient semiconductor layer, and/or a semiconductor layer overlaying another semiconductor layer of a different type, such as a silicon layer on a silicon germanium layer.

One or more semiconductor devices 620 are formed on an upper surface of the substrate 610. For example, one or more active devices, such as transistors, are formed on the upper surface of the substrate 610. According to some embodiments of the present disclosure, the transistors include field-effect transistors (FETs), which are categorized into planar-type FETs, fin-type FETs (FinFETs), gate-all-around (GAA) FETS, nanosheet FETs, nanowire FETs, or the like. The semiconductor devices 620 may also include passive devices, such as diodes, resistors, capacitors, inductors, fuses, and the like. According to some embodiments, each of the semiconductor devices 620 includes one or more input and output terminals for receiving and providing power or signals. According to some embodiments of the present disclosure, each of the semiconductor devices 620 includes an array of memory cells. Each of the semiconductor devices 620 may further include memory control circuits.

Referring to FIG. 6B, according to some embodiments of the present disclosure, an interconnect layer 630 is formed over the substrate 610. The interconnect layer 630 may be formed of a plurality of metallization layers each including a conductive line layer or a conductive via layer. Each of the conductive line layers includes a plurality of parallel conductive lines, while each of the conductive via layers include a plurality of conductive vias. The conductive line layers may be alternatively arranged with the conductive via layers. The conductive vias in each conductive via layer are configured to electrically connect one conductive line in the overlying conductive line layer to another conductive line in the underlying conductive line layer. As a result, an interconnect structure is formed in the interconnect layer 630 to interconnect the input/output terminals of the semiconductor devices 620 in the substrate 610 or interconnect the semiconductor devices 620 to overlying circuits or devices.

According to some embodiments of the present disclosure, the interconnect layer 630 includes one or more conductive pads 640 at a topmost sublayer of the interconnect layer 630. The conductive pads 640 may be formed as conductive lines in a manner similar to that for forming the conductive lines in a metallization layer. The conductive pads 640 may be exposed through the front side 130F, 140F of the substrate 610, and serve as bond pads of the subsequently-formed first or second semiconductor dies 130, 140.

According to some embodiments of the present disclosure, the semiconductor devices 620 or the interconnect layer 630 are formed through a sequence of semiconductor processes, which may include at least one of e.g., a photolithography operation, an exposure operation, an etching operation, an ion implantation, an annealing operation, an alignment operation, a cleaning operation, a deposition operation, a bonding operation, a singulation operation, a testing operation and the like. Through the sequence of semiconductor processes, the semiconductor devices 620 may include one or more conductive layers, dielectric layers, and semiconductor layers to provide specific functions as designed.

Referring to FIG. 6C, the substrate 610 is flipped and arranged on a substrate 604. According to some embodiments of the present disclosure, the substrate 604 is a carrier substrate. The substrate 604 may include a semiconductor material, such as bulk silicon or other suitable semiconductor materials. According to some other embodiments, the substrate 604 is formed of glass, ceramics, or other substrate materials.

The substrate 602 is removed from the substrate 610. According to some embodiments, the substrate 602 is removed by an etching operation or through de-bonding a release film (not separately shown) arranged between the substrate 602 and the substrate 610.

According to some embodiments of the present disclosure, the substrate 610 is thinned from the backside 130B/140B of the substrate 610. The thinning operation may be performed by CMP, mechanical grinding, laser etching, or other thinning operations.

Referring to FIG. 6D, a singulation operation is performed to separate the semiconductor devices 620 on the substrate 610 into individual semiconductor dies 130, 140. The singulation operation may be performed by a cutting tool 650, e.g., a diamond blade, a laser blade, or the like. The singulation operation may be performed to cut through scribe lines between the plurality of semiconductor devices 620.

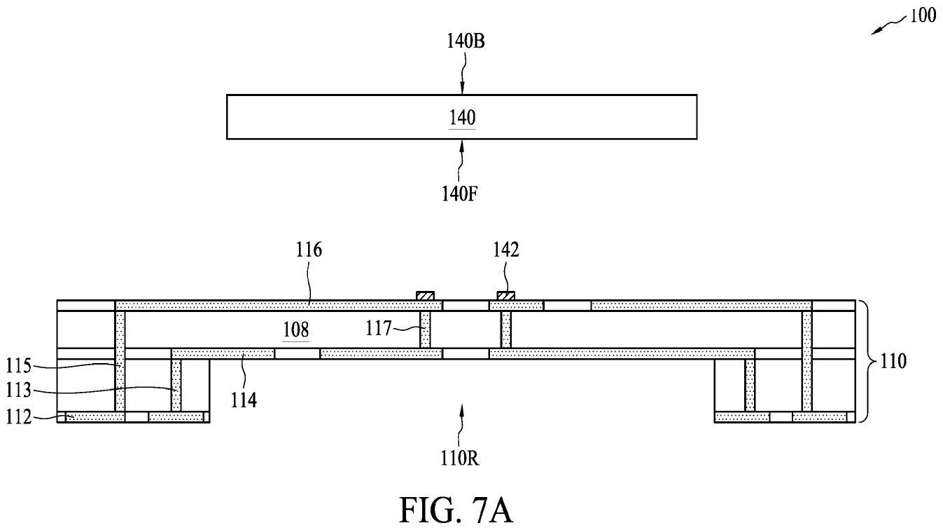

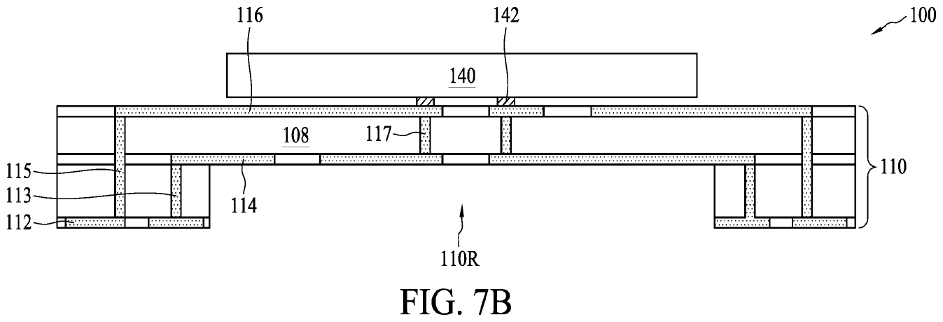

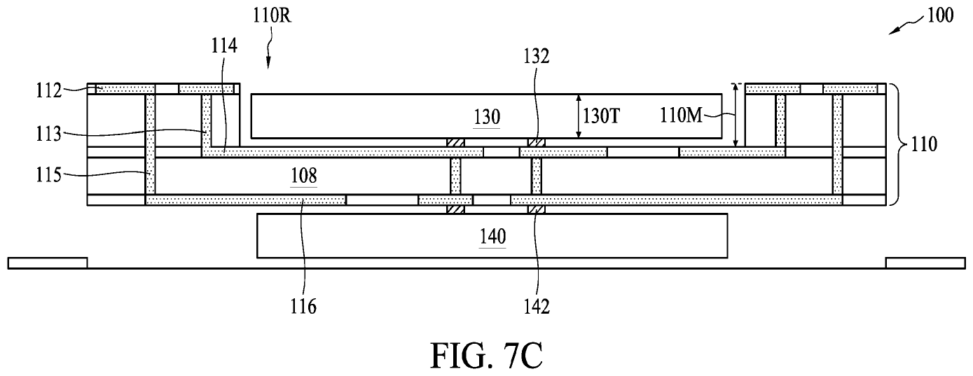

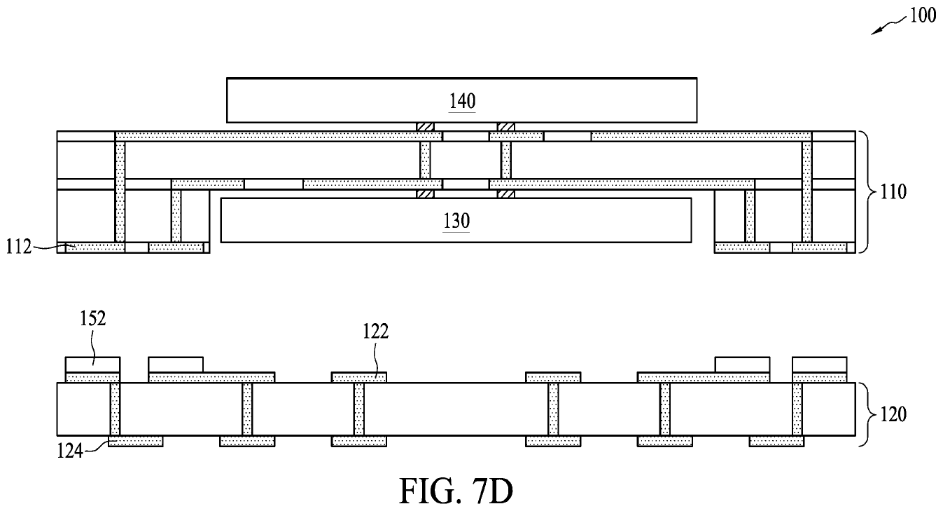

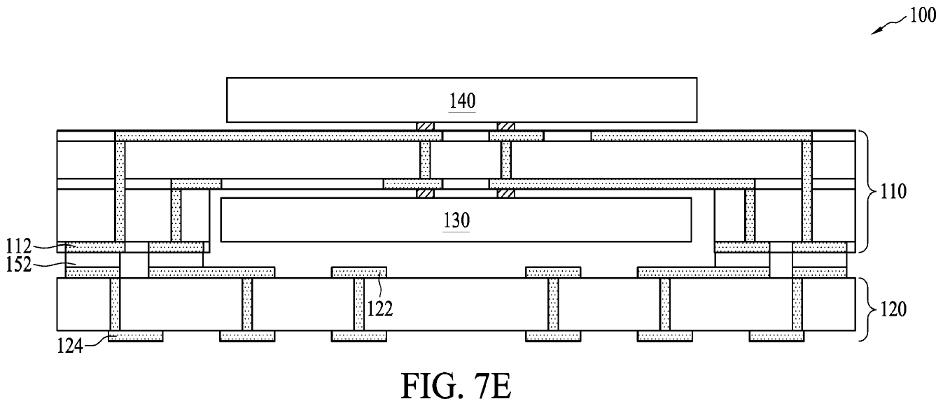

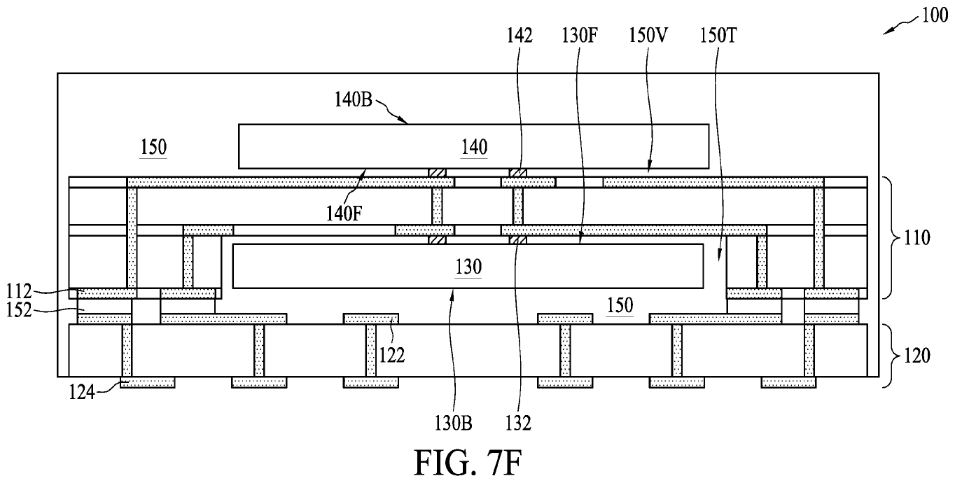

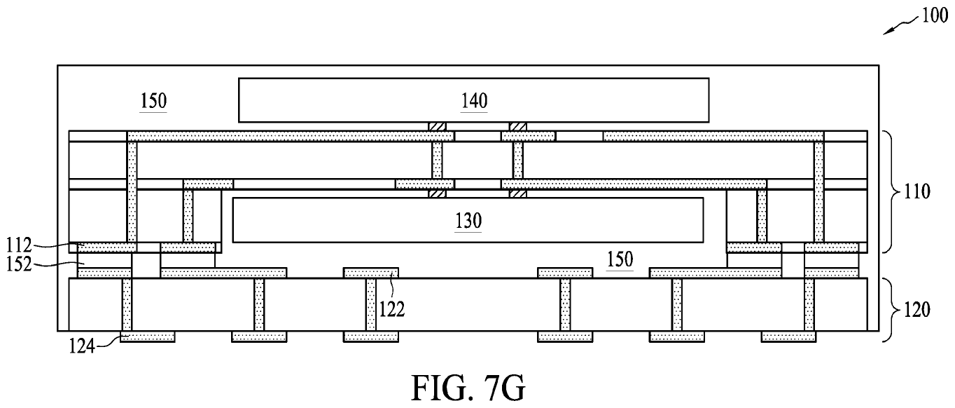

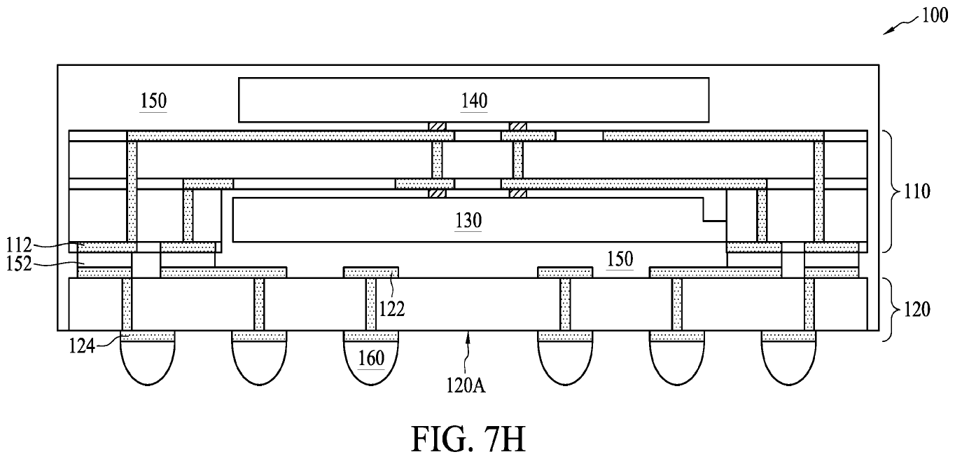

FIGS. 7A to 7H are schematic cross-sectional views of intermediate stages of a method 700 of forming the semiconductor package structure 100, in accordance with some embodiments of the present disclosure. It is understood that additional steps can be provided before, during, and after the steps shown by FIGS. 7A to 7H, and some of the steps described below can be replaced or eliminated in additional embodiments of the method 700. The order of the steps may be interchangeable.

Referring to FIG. 7A, the fabricated second semiconductor die 140 and the first substrate 110 are transported into a bonded tool (not separately shown). According to some embodiments of the present disclosure, the second semiconductor die 140 is moved to a location over the first substrate 110. An alignment operation is performed to align the second semiconductor die 140 with the first substrate 110.

Referring to FIG. 7B, the second semiconductor die 140 is moved toward (e.g., in a downward direction) the first substrate 110 and bonded to the first substrate 110. The bond pads (not separately shown) of the second semiconductor die 140 are aligned with the conductive pads 142 of the first substrate 110. The second semiconductor die 140 is bonded to the bond pads 142 of the first substrate 110. According to some embodiments of the present disclosure, the conductive pads 142 are not formed on the first substrate initially but formed on the front side 140F of the second semiconductor die 140 and bonded to the first substrate 110. According to some embodiments of the present disclosure, referring to FIGS. 3F and 7B, the second semiconductor die 140 is bonded to the second side 110B of the horizontal portion 110H. According to some embodiments of the present disclosure, the bonding operation may include a flip-chip bonding, a thermal bonding, a thermo-compression bonding, an ultrasonic bonding, a hybrid bonding, or the like.

Referring to FIG. 7C, the bonded semiconductor package structure 100 and the fabricated first semiconductor die 130 is transported into a bonding tool (not separately shown). The bonded semiconductor package structure 100 is flipped. According to some embodiments of the present disclosure, the first semiconductor die 130 is aligned with the recess 110R of the first substrate 110. The first semiconductor die 130 is then bonded to the first substrate 110 through the conductive pads 132 within the recess 110R. According to some embodiments of the present disclosure, referring to FIGS. 3F and 7C, the first semiconductor die 130 is bonded to the first side 110A of the horizontal portion 110H. The first semiconductor die 130 may be laterally surrounded by the protrusion portion 110P. According to some embodiments of the present disclosure, the thickness 130T of the first semiconductor die 130 is greater than, substantially equal to, or less than the height 110M of the protrusion portion 110P.

FIGS. 7D to 7E illustrate the bonding of second substrate 120 to the semiconductor package structure 100. Referring to FIG. 7D, the semiconductor package structure 100 and the second substrate 120 are transported into a bonded tool (not separately shown). According to some embodiments of the present disclosure, the semiconductor package structure 100 is moved to a location over the second substrate 120. An alignment operation is performed to align the semiconductor package structure 100 with the second substrate 120. The conductive lines 112 of the first substrate 110 are aligned with the bonding members 152 of the second substrate 120.

Referring to FIG. 7E, the semiconductor package structure 100 is moved toward (e.g., in a downward direction) the second substrate 120 and bonded to the second substrate 120. The conductive lines 112 are bonded to the bonding members 152 of the second substrate 120. According to some embodiments of the present disclosure, referring to FIGS. 3F and 7E, the second substrate 120 is bonded to the protrusion portion 110P of the first substrate 110. The first semiconductor die 130 is surrounded by the first substrate 110 and the second substrate 120. According to some embodiments of the present disclosure, the bonding operation may include a flip-chip bonding, a thermal bonding, a thermo-compression bonding, an ultrasonic bonding, a hybrid bonding, or the like.

Referring to FIG. 7F, a molding material 150 is used to encapsulate the first substrate 110, the second substrate 120, the first semiconductor die 130, the second semiconductor die 140, and conductive pads 132, 142 and the bonding members 152. The molding material may include epoxy resin, PI, BCB, PBO, or PEEK, or the like. The molding material 150 may fill the space 150T of the recess 110R between the first substrate 110 and the first semiconductor die 130 and the space 150V between the first substrate 110 and the second substrate 120. According to some embodiments of the present disclosure, the molding material 150 encapsulates or laterally surrounds the bonding members 152 and the conductive pads 132, 142. The encapsulating operation may include injection molding or other suitable molding processes.

Referring to FIG. 7G, excess portions of the molding material 150 are removed or thinned. The thinning operation may reduce a thickness of the molding material 150. The thinning operation may keep the backside 140B of the second semiconductor die 140 covered by the molding material 150. The thinning operation may include CMP, mechanical grinding, laser etching, or the like.

Referring to FIG. 7H, connectors 160 are formed on the first side 120A of the second substrate 120. According to some embodiments of the present disclosure, the connectors 160 are formed on the corresponding conductive lines 124. The connectors 160 may include a solder material. According to some embodiments of the present disclosure, the solder material includes Sn, Pb, Ni, Au, Ag, Cu, Bi, combinations thereof, or mixtures of other electrically conductive material. According to some other embodiments, the solder material includes a lead-based material, such as SnAg, SnPb, SnAgCu, or the like. According to some other embodiments of the present disclosure, the solder material is a lead-free material. According to some embodiments of the present disclosure, the connectors 160 are fabricated by ball dropping, solder pasting, stencil printing or any other suitable operations. In some embodiments, the connectors 160 are reflowed after being deposited. As discussed previously, the connectors 160 may form an array that occupies an area overlapping the recess 110R from a bottom-view or top-view perspective. The bonding area of the connectors 160 is thus increased than an existing bonding structure in the absence of the second substrate 120. The bonding performance of the semiconductor package structure 100 is improved accordingly.

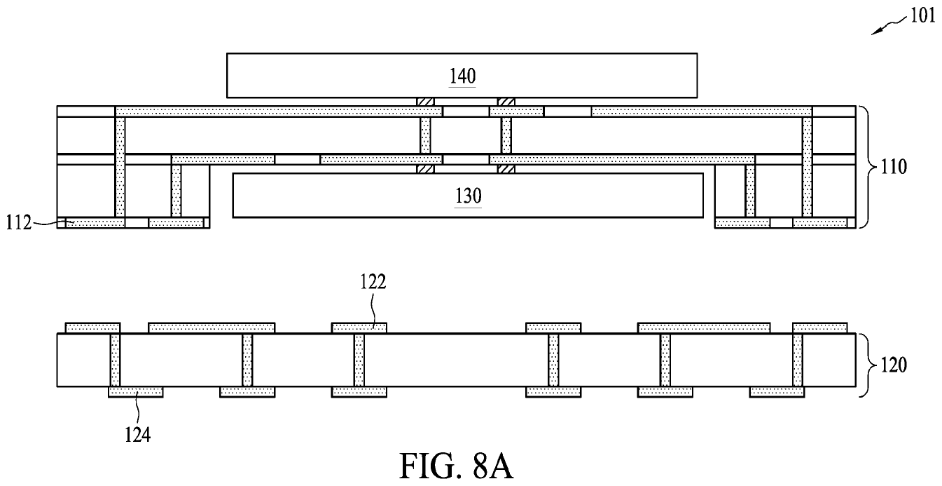

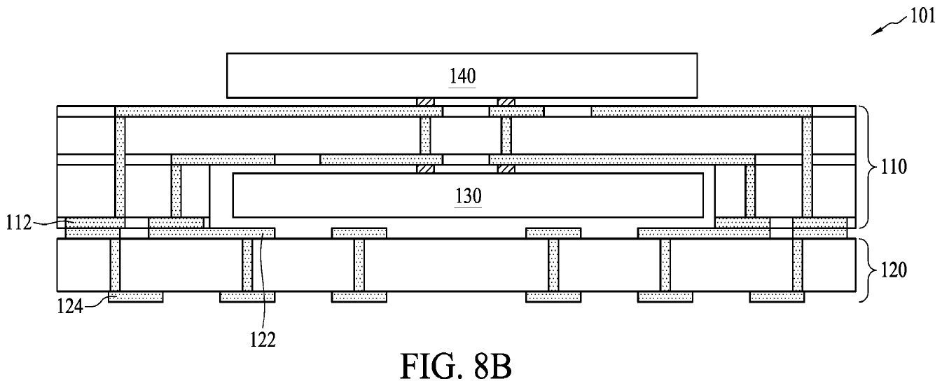

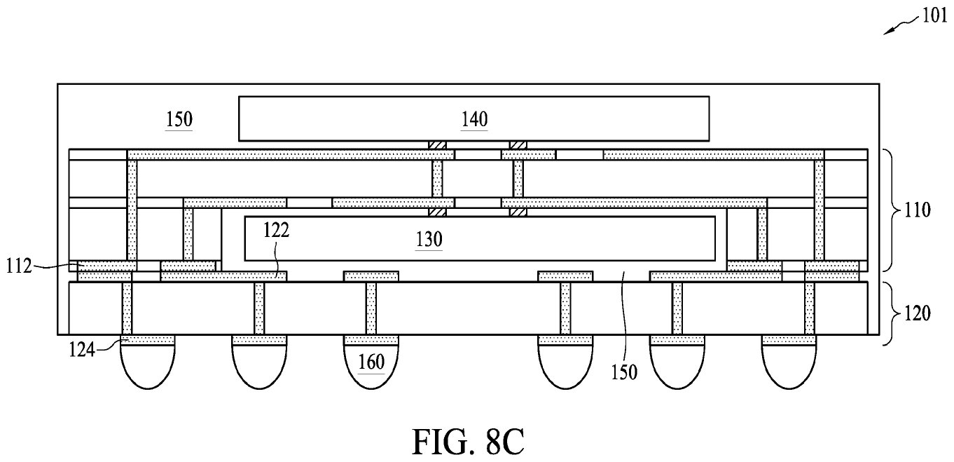

FIGS. 8A to 8C are schematic cross-sectional views of intermediate stages of a method 800 of forming a semiconductor package structure 101, in accordance with some embodiments of the present disclosure. It is understood that additional steps can be provided before, during, and after the steps shown by FIGS. 8A to 8C, and some of the steps described below can be replaced or eliminated in additional embodiments of the method 800. The order of the steps may be interchangeable. The structure and method for forming the semiconductor package structure 101 are similar to those for forming the semiconductor package structure 100, and thus the similar features will not be repeated herein.

Referring to FIG. 8A, the first substrate 110 with bonded with the first semiconductor die 130 and the second semiconductor die 140 is transported into a bonding tool (not separately shown). Also, the second substrate 120 is transported into the bonding tool. Referring to FIGS. 7D and 8A, the second substrate 120 shown in FIG. 8A does not include the bonding members 152.

Referring to FIG. 8B, the bonded first substrate 110 is bonded directly to the second substrate 120 in the absence of the bonding members 152. According to some embodiments of the present disclosure, the conductive lines 112 of the first substrate 110 are bonded to the conductive lines 122 of the second substrate 120, in which the metal atoms of the conductive lines 112 and 122 form metallic bonds to thereby bond the first substrate 110 to the second substrate 120. According to some embodiments of the present disclosure, the bonding operation shown in FIG. 8B includes a thermos-compressive bonding.

Referring to FIG. 8C, the molding material 150 is employed to encapsulate the first substrate 110, the second substrate 120, the first semiconductor die 130 and the second semiconductor die 140 in a manner similar to that illustrated in FIG. 7F. Moreover, the molding material 150 is thinned, and the connectors 160 are formed on the second substrate 120 in manners similar to the processes shown in FIG. 7G and FIG. 7H.

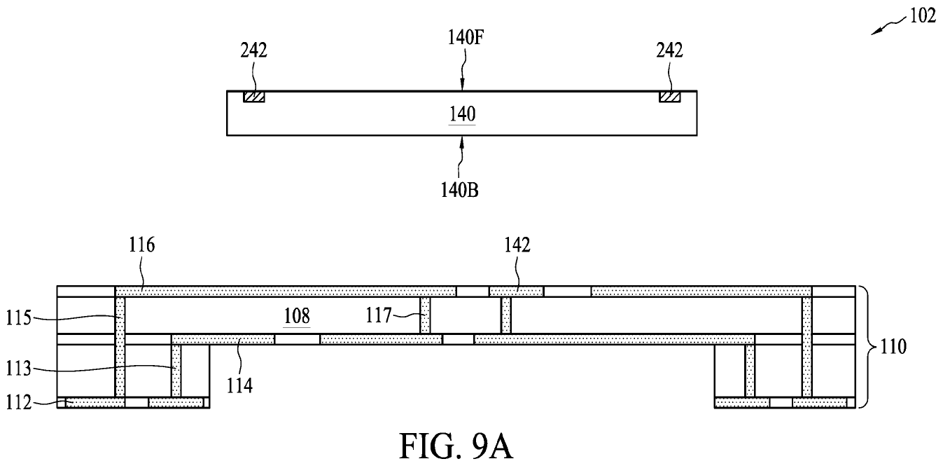

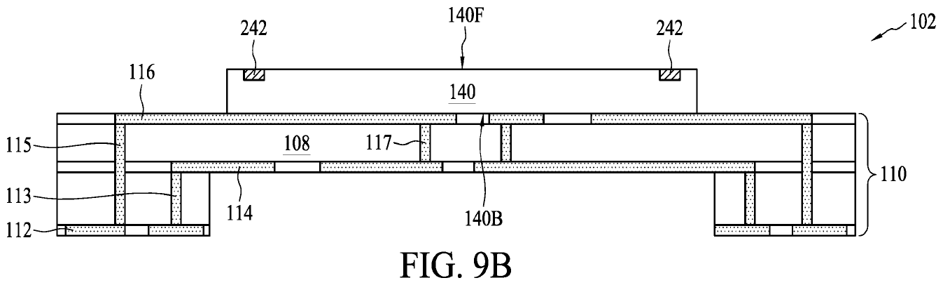

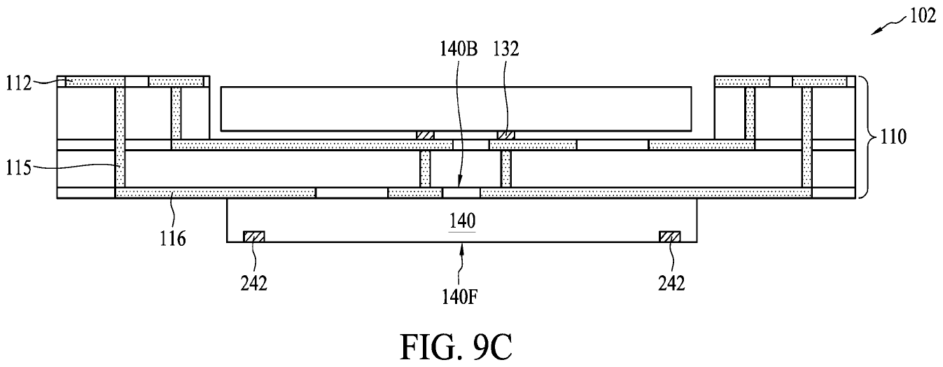

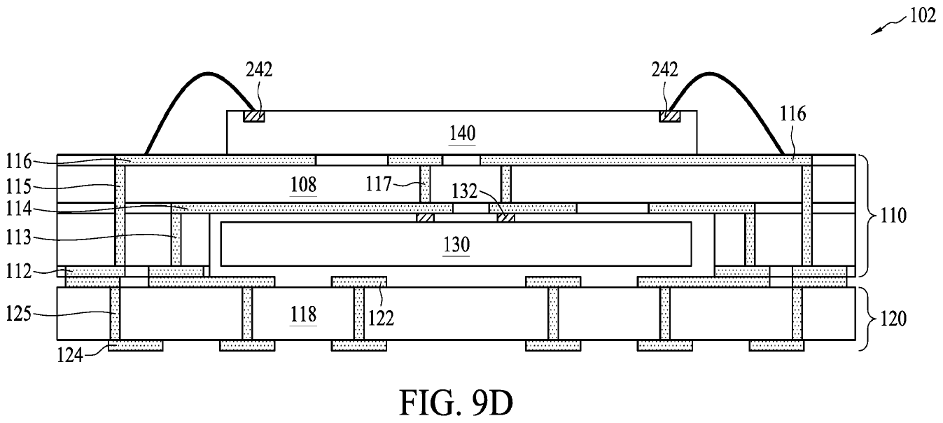

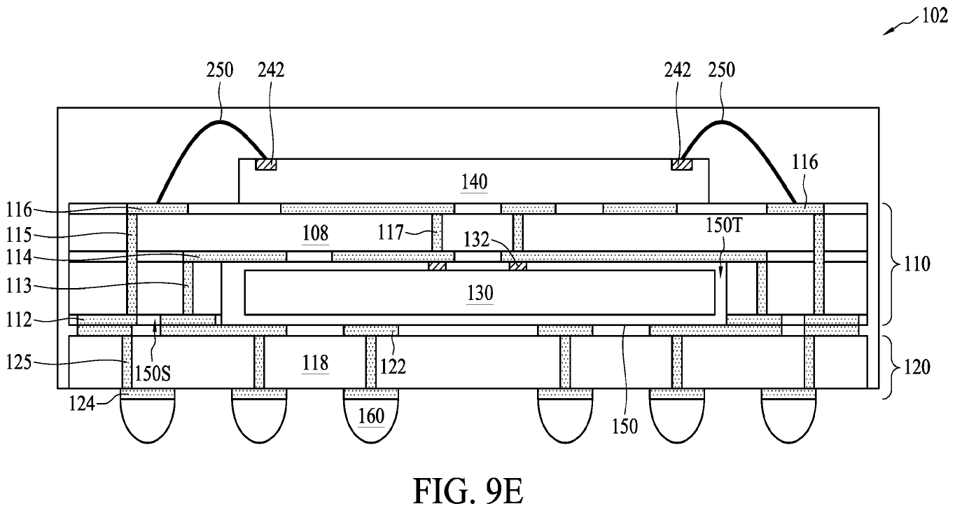

FIGS. 9A to 9E are schematic cross-sectional views of intermediate stages of a method 900 of forming a semiconductor package structure 102, in accordance with some embodiments of the present disclosure. It is understood that additional steps can be provided before, during, and after the steps shown by FIGS. 9A to 9E, and some of the steps described below can be replaced or eliminated in additional embodiments of the method 900. The order of the steps may be interchangeable. The structure and method for forming the semiconductor package structure 102 are similar to those for forming the semiconductor package structure 101, and thus the similar features will not be repeated herein.

Referring to FIG. 9A, the first substrate 110 bonded with the first semiconductor die 130 and the second semiconductor die 140 is transported into a bonding tool. Also, a second substrate 120 is transported into the bonding tool. Referring to FIGS. 8A and 9A, the second semiconductor die 140 shown in FIG. 9A is arranged to cause its backside 140B to face the first substrate 110 and its front side 140F to face away from the first substrate 110. According to some embodiments of the present disclosure, the second semiconductor die 140 includes conductive pads 242 formed on the front side 140F and serving as the bond pads. According to some embodiments of the present disclosure, the second semiconductor die 140 does not include any bond pads on the backside 140B of the second semiconductor die 140. The entire backside 140B of the second semiconductor die 140 may be formed of bulk silicon.

Referring to FIG. 9B, the second semiconductor die 140 is moved toward (e.g., in a downward direction) the first substrate 110 and bonded to the first substrate 110. The bond pads 242 of the second semiconductor die 140 are kept facing away from the first substrate 110. The backside 140B of the second semiconductor die 140 is electrically insulated from the first substrate 110.

Referring to FIG. 9C, the semiconductor package structure 102 and the fabricated first semiconductor die 130 are transported into a bonding tool (not separately shown). The semiconductor package structure 102 is flipped. According to some embodiments of the present disclosure, an alignment operation is performed to align the first semiconductor die 130 with the recess 110R of the first substrate 110. The first semiconductor die 130 is then bonded to the first substrate 110 through the conductive pads 132 within the recess 110R.

FIG. 9D illustrates the bonding of second substrate 120 to the semiconductor package structure 102. The semiconductor package structure 102 and the second substrate 120 are transported into a bonded tool (not separately shown). According to some embodiments of the present disclosure, the semiconductor package structure 102 is moved to a location over the second substrate 120. An alignment operation is performed to align the semiconductor package structure 102 with the second substrate 120. Subsequently, the semiconductor package structure 102 is moved toward (e.g., in a downward direction) the second substrate 120 and bonded to the second substrate 120. The conductive lines 112 of the first substrate 110 are aligned with conductive lines 122 of the second substrate 120 (or the bonding members 152 in the presence of the bonding members 152). The conductive lines 112 are bonded to the conductive lines 122 of the second substrate 120 (or bonding members 152 in the presence of the bonding members 152). According to some embodiments of the present disclosure, the bonding operation may include a flip-chip bonding, a thermal bonding, a thermo-compression bonding, an ultrasonic bonding, a hybrid bonding, or the like.

Wired bonding is performed to electrically couple the second semiconductor die 140 to the first substrate 110 through the conductive lines 116, the conductive lines 250 and the conductive pads 242. Two ends of each of the conductive lines 250 are bonded to the conductive lines 116 and the conductive pads 242 through a ball bonding operation, a wedge bonding operation, or the like.

Referring to FIG. 9E, a molding material 150 is used to encapsulate the first substrate 110, the second substrate 120, the first semiconductor die 130 and the second semiconductor die 140. The molding material 150 may include epoxy resin, PI, BCB, PBO, or PEEK, or the like. The molding material 150 may fill the space 150T of the recess 110R between the first substrate 110 and the first semiconductor die 130 and the space 150S between the first substrate 110 and the second substrate 120. According to some embodiments of the present disclosure, the molding material 150 encapsulates or laterally surrounds the bonding members 152 and the conductive pads 132, 242. The encapsulating operation may include injection molding or other suitable molding processes.

According to some embodiments of the present disclosure, excess portions of the molding material 150 are removed or thinned. The thinning operation 150 may reduce a thickness of the molding material 150. The thinning operation may include CMP, mechanical grinding, laser etching, or the like.

According to some embodiments of the present disclosure, connectors 160 are formed on the first side 120A of the second substrate 120. According to some embodiments of the present disclosure, the connectors 160 are formed on the corresponding conductive lines 124 in a manner similar to that described with reference to FIG. 7H.

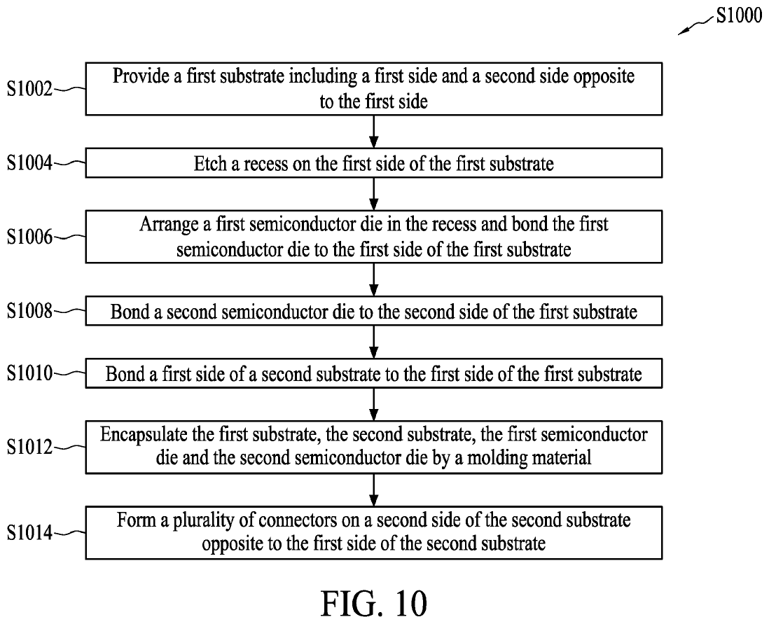

FIG. 10 shows a schematic flowchart of a method 1000 of forming a semiconductor package structure, in accordance with some embodiments of the present disclosure. It is understood that additional steps can be provided before, during, and after the steps shown by FIG. 10, and some of the steps described below can be replaced or eliminated in additional embodiments of the method S1000. The order of the steps may be interchangeable. The semiconductor package structure may be similar to the semiconductor package structure 100, 101, or 102.

At step S1002, a first substrate, e.g., the substrate 110, is provided, which includes a first side, e.g., the first side 110A, and a second side, the second side 110B, opposite to the first side.

At step S1004, a recess, e.g., the recess 110R, is etched on the first side of the first substrate.

At step S1006, a first semiconductor die, e.g., the first semiconductor die 130, is arranged in the recess, and the first semiconductor die is bonded to the first side of the first substrate.

At step S1008, a second semiconductor die, e.g., the second semiconductor die 140, is bonded to the second side of the first substrate. The order of steps S1006 and S1008 may be interchanged.

At step S1010, a second substrate e.g., the second substrate 120, is bonded to the first side of the first substrate. According to some embodiments, the second substrate includes a first side, e.g., the first side 120B, and a second side, e.g., the second side 120A, opposite to the first side of the second substrate. The first side of the second substrate, is bonded to the first side of the first substrate.

At step S1012, the first substrate, the second substrate, the first semiconductor die, and the second semiconductor die are encapsulated by a molding material, e.g., the molding material 150.

At step S1014, a plurality of connectors is formed on the second side of the second substrate opposite to the first side of the second substrate.

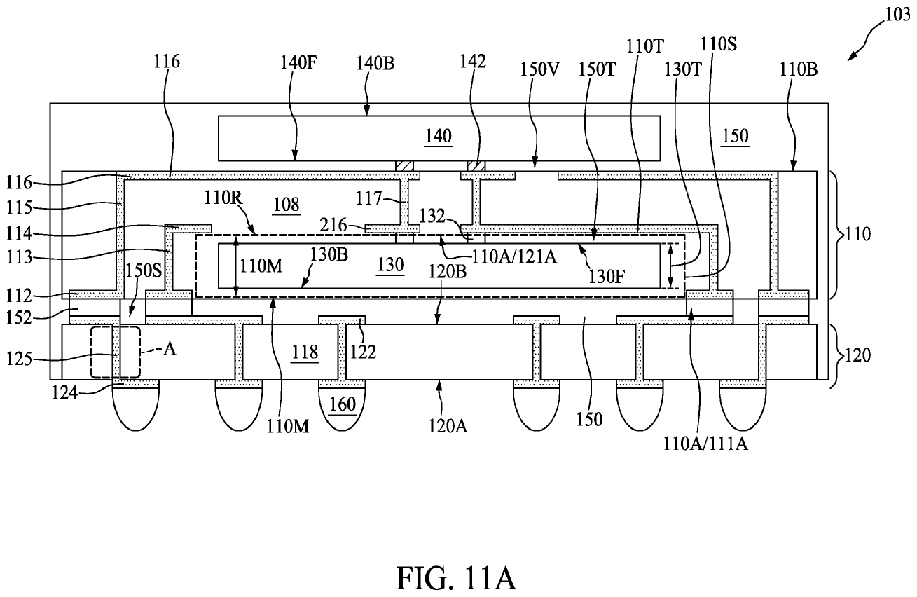

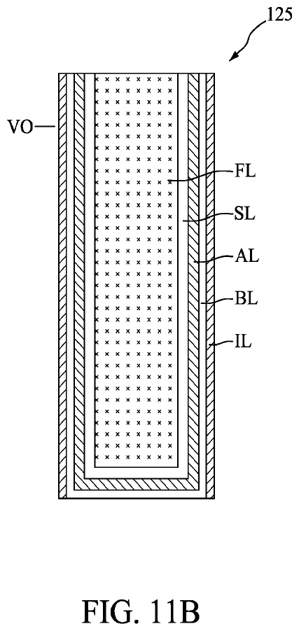

FIG. 11A shows a cross-sectional view of a semiconductor package structure 103, in accordance with various embodiments of the present disclosure. FIG. 11B shows a schematic close-up cross-sectional view diagram of dotted area A as shown in FIG. 11A, in accordance with one embodiment of the present disclosure. The semiconductor package structure 103 is similar to the semiconductor package structure 100 in many aspects, and thus these similar features will not be repeated herein. The main differences are described as follows.

Referring to FIGS. 11A and 11B, the conductive vias 125 may include a filler layer FL, a seed layer SL, an adhesive layer AL, a barrier layer BL, and two isolation layers IL.

With refer to FIG. 11B, the two isolation layers IL may be conformally formed on two sidewalls of the via opening VO. According to some embodiments of the present disclosure, the two isolation layers IL may be formed of, for example, silicon oxide, silicon nitride, silicon oxynitride, or tetra-ethyl ortho-silicate. The two isolation layers IL may have a thickness between about 50 nm and about 200 nm. Alternatively, in some embodiments, the two isolation layers IL may be formed of, for example, parylene, epoxy, or poly(p-xylene). The two isolation layers IL may have a thickness between about 1 μm and about 5 μm. The two isolation layers IL may ensure the filler layer FL is electrically isolated in the second substrate 120.

According to some embodiments of the present disclosure, the barrier layer BL may be conformally formed on the isolation layer IL and on the bottom surface of the via opening VO. The barrier layer BL may have a U-shaped cross-sectional profile. The barrier layer BL may be formed of, for example, tantalum, tantalum nitride, titanium, titanium nitride, rhenium, nickel boride, or tantalum nitride/tantalum bilayer. The barrier layer BL may inhibit diffusion of the conductive materials of the filler layer FL into the isolation layer IL. The barrier layer BL may be formed by deposition process such as physical vapor deposition, atomic layer deposition, chemical vapor deposition, or sputtering.

According to some embodiments of the present disclosure, the adhesive layer AL may be conformally formed on the barrier layer BL and may have a U-shaped cross-sectional profile. The adhesive layer AL may be formed of, for example, titanium, tantalum, titanium tungsten, or manganese nitride. The adhesive layer AL may improve an adhesion between the seed layer SL and the barrier layer BL. The adhesive layer AL may have a thickness between about 5 nm and about 50 nm. The adhesive layer AL may be formed by deposition process such as physical vapor deposition, atomic layer deposition, chemical vapor deposition, or sputtering.

According to some embodiments of the present disclosure, the seed layer SL may be conformally formed on the adhesive layer AL and may have a U-shaped cross-sectional profile. The seed layer SL may have a thickness between about 10 nm and about 40 nm. The seed layer SL may be formed of, for example, copper or ruthenium. The seed layer SL may be formed by deposition process such as physical vapor deposition, atomic layer deposition, chemical vapor deposition, or sputtering. The seed layer SL may reduce resistivities of the via opening VO during the formation of the filler layer FL by an electroplating process.

According to some embodiments of the present disclosure, the filler layer FL may be formed on the seed layer SL and completely fill the via opening VO. The filler layer FL may be, for example, copper. The filler layer FL may be formed by an electroplating process.

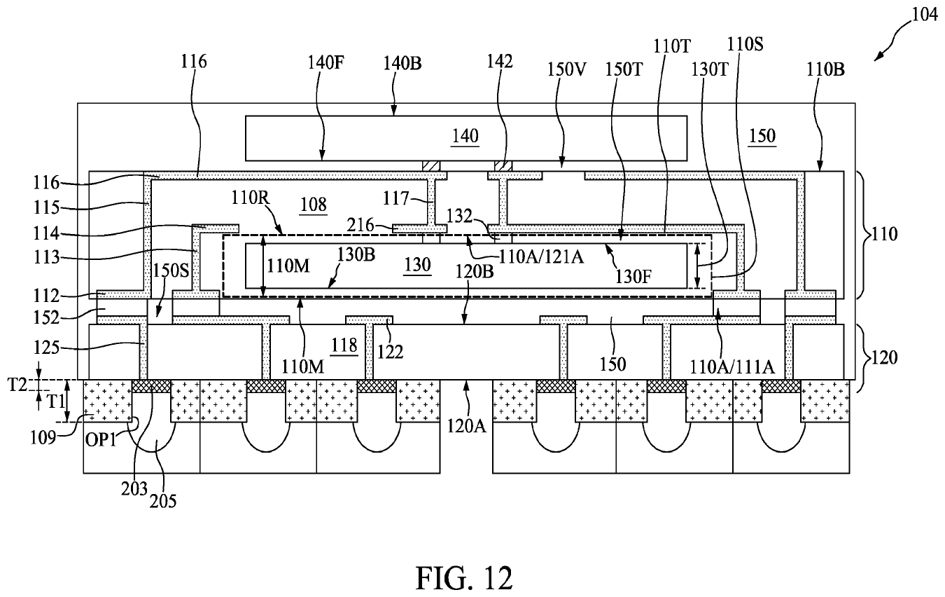

FIG. 12 shows a cross-sectional view of a semiconductor package structure 104, in accordance with various embodiments of the present disclosure. The semiconductor package structure 104 is similar to the semiconductor package structure 100 in many aspects, and thus these similar features will not be repeated herein. The main differences are described as follows.

Referring to FIG. 12, the first passivation layer 109 may be disposed on the second substrate 120. According to some embodiments of the present disclosure, the first passivation layer 109 may be a single layer structure or a multi-layer structure. In some embodiments, the first passivation layer 109 may include polybenzoxazole, polyimide, benzocyclobutene, solder resist film, the like, or a combination thereof. In some other embodiments, the first passivation layer 109 may be a dielectric layer. The dielectric layer may include a nitride such as silicon nitride, an oxide such as silicon oxide, an oxynitride such as silicon oxynitride, silicon nitride oxide, phosphosilicate glass, borosilicate glass, boron-doped phosphosilicate glass, or a combination thereof.

With reference to FIG. 12, a first opening OP1 may be disposed along the first passivation layer 109 to expose a portion of the pad layer 201. According to some embodiments of the present disclosure, the sidewalls of the first opening OP1 may be substantially vertical. According to some embodiments of the present disclosure, the sidewalls of the first opening OP1 may be tapered. It should be noted that, in the description of the present disclosure, a surface is “substantially vertical” if there exists a vertical plane from which the surface does not deviate by more than three times the root mean square roughness of the surface.

With reference to FIG. 12, the first barrier layer 203 may be disposed on the second substrate 120 and in the first opening OP1 of the first passivation layer 109. According to some embodiments of the present disclosure, the first barrier layer 203 may have a thickness T1 less than a thickness T2 of the first passivation layer 109. The first barrier layer 203 may include aluminum fluoride. Due to saturated bonding property of aluminum fluoride, it is stable and may prevent the conductive via 125 from corrosion from various semiconductor processes, especially those processes including fluorine ions. In some embodiments, the first barrier layer 203 may further include zinc oxide which may increase electrical properties of the first barrier layer 203. In some embodiments, the content of zinc oxide may be greater than the content of aluminum fluoride.

With reference to FIG. 12, the first connector 205 may be disposed on the first barrier layer 203. According to some embodiments of the present disclosure, the upper portion of the first connector 205 may be extending to the first passivation layer 109, completely filled the first opening OP1, and disposed on the first barrier layer 203. The lower portion of the first connector 205 may be protruding from a plane coplanar with the top surface of the first passivation layer 109 and disposed on the upper portion of the first connector 205. According to some embodiments of the present disclosure, the first connector 205 may include a conductive material with low resistivity, such as tin, lead, silver, copper, nickel, bismuth, or an alloy thereof.

According to some embodiments of the present disclosure, the first connector 205 may be a solder joint. The solder joint may comprise a material such as tin, or other suitable material, such as silver or copper. In an embodiment in which the solder joint is tin solder joint, the solder joint may be formed by initially forming a layer of tin through evaporation, electroplating, printing, solder transfer, or ball placement to a thickness of about 10 μm to about 100 μm. Once the layer of tin has been formed and filled the first opening OP1 and on the first passivation layer 109, a reflow process may be performed to shape the solder joint into the desired shape.

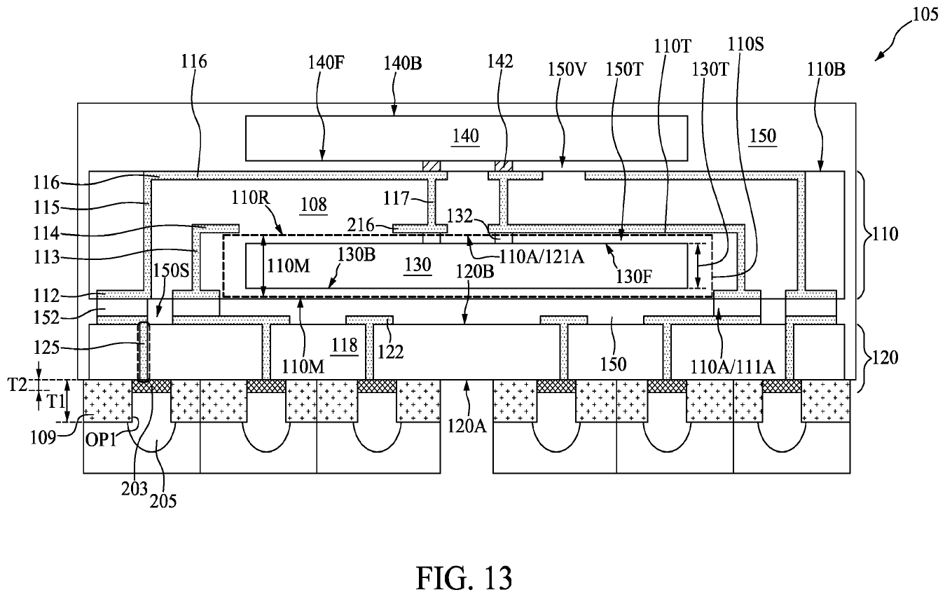

FIG. 13 shows a cross-sectional view of a semiconductor package structure 105, in accordance with various embodiments of the present disclosure. The semiconductor package structure 105 is similar to the semiconductor package structure 100 in many aspects, and thus these similar features will not be repeated herein. The main differences are described as follows.

Referring to FIG. 13, the semiconductor package structure 105 includes the plurality of conductive vias 125 (as shown in FIG. 11A), the first barrier layer 203, the first connector 205, and the first passivation layer 109 (as shown in FIG. 12). Therefore, the semiconductor package structure 105 may have the relevant characteristics and advantages mentioned above.

Although the present disclosure and its advantages have been described in detail, it should be understood that various changes, substitutions, and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor structure, comprising:
a first substrate having a first side and a second side opposite to the first side, wherein the first side includes a recess recessed from the first side;
a first semiconductor die arranged in the recess and bonded to the first side of the first substrate;
a second semiconductor die bonded to the second side of the first substrate;
a second substrate electrically bonded to the first side of the first substrate;
a plurality of conductive vias positioned along the second substrate and extending through the second substrate;
a passivation layer positioned on the second substrate; and
a barrier layer positioned on the second substrate and in the passivation layer.

2. The semiconductor structure of claim 1, wherein the conductive via comprises:
two isolation layers conformally formed on two sidewalls of the via opening;
a via barrier layer conformally formed on the isolation layer IL and on the bottom surface of the via opening, wherein the via barrier layer has a U-shaped cross-sectional profile and is formed of tantalum, tantalum nitride, titanium, titanium nitride, rhenium, nickel boride, or tantalum nitride/tantalum bilayer;
an adhesive layer conformally formed on the barrier layer, wherein the adhesive layer has a U-shaped cross-sectional profile and is formed of titanium, tantalum, titanium tungsten, or manganese nitride;
a seed layer conformally formed on the adhesive layer, wherein the seed layer has a U-shaped cross-sectional profile and is formed of copper or ruthenium; and
a filler layer formed on the seed layer and completely fill the via opening, wherein the filler layer is copper.

3. The semiconductor structure of claim 2, wherein the two isolation layers are formed of silicon oxide, silicon nitride, silicon oxynitride, or tetra-ethyl ortho-silicate.

4. The semiconductor structure of claim 3, wherein the two isolation layers have a thickness between about 50 nm and about 200 nm.

5. The semiconductor structure of claim 2, wherein the two isolation layers are formed of parylene, epoxy, or poly(p-xylene).

6. The semiconductor structure of claim 5, wherein the two isolation layers have a thickness between about 1 μm and about 5 μm.

7. The semiconductor structure of claim 2, wherein the adhesive layer has a thickness between about 5 nm and about 50 nm.

8. The semiconductor structure of claim 2, wherein the seed layer has a thickness between about 10 nm and about 40 nm.

9. The semiconductor structure of claim 1, wherein the passivation layer defines a plurality of openings disposed along the passivation layer to expose a portion of the second substrate.

10. The semiconductor structure of claim 9, wherein the barrier layer is positioned in the openings.

11. The semiconductor structure of claim 1, wherein a thickness of the passivation layer is greater than a thickness of the barrier layer.

12. The semiconductor structure of claim 11, further comprising a connector positioned on the barrier layer.

13. The semiconductor structure of claim 12, wherein a first portion of the connector is extending to the passivation layer, completely filled the opening, and disposed on the barrier layer.

14. The semiconductor structure of claim 13, wherein a second portion of the connector is protruding from a plane coplanar with the top surface of the passivation layer and disposed on the first portion of the connector.

15. The semiconductor structure of claim 1, wherein the passivation layer is made of polybenzoxazole, polyimide, benzocyclobutene, solder resist film, the like, or a combination thereof.

16. The semiconductor structure of claim 1, wherein the passivation layer is made of silicon nitride, silicon oxide, silicon oxynitride, silicon nitride oxide, phosphosilicate glass, borosilicate glass, boron-doped phosphosilicate glass, or a combination thereof.

17. The semiconductor structure of claim 1, wherein the barrier layer is made of aluminum fluoride, or zinc oxide.

18. The semiconductor structure of claim 9, wherein the sidewall of the opening is substantially vertical or tapered.

19. The semiconductor structure of claim 12, wherein the connector is a solder joint.

20. The semiconductor structure of claim 19, wherein the solder joint is made of tin, silver, or copper.
